(19) United States
(12) Patent Application Publication
(10) Pub. No.: US 2009/0205701 A1
(43) Pub. Date: Aug. 20, 2009

(54) LUMINESCENT SOLAR COLLECTOR HAVING CUSTOMIZABLE VIEWING COLOR

(75) Inventors: Luc C. Govaerts, Hoogstraten (BE); Theodorus Lambertus Hoeks, Bergen op Zoom (NL); Jeremy D. Hurst, Rotterdam (NL); Marcus Zettl, Grosshelfendorf (DD)

Correspondence Address: SABIC - LEXAN;SABIC Innovative Plastics - IP Legal, ONE PLASTICS AVE., PITTSFIELD, MA, 01201-3697, US

(73) Assignee: General Electric Company, Schenectady, NY (US)

(21) Appl. No.: 11/615,398

(22) Filed: Dec. 22, 2006

(51) Int. Cl. H01L 31/055

(52) U.S. Cl. 136/247

(57) ABSTRACT

A luminescent solar collector is provided comprising a sheet and a light energy converter, such as a photocell. The sheet comprises two polymer layers. One polymer layer comprises a polymer and a fluorescent dye or quantum dot. The other polymer layer comprises a polymer and a non-fluorescent dye, and may further comprise an organic diffuser. The luminescent solar collector can be customized to any desired viewing color and provides a high level of edge emission.

### CROSS-REFERENCE TO RELATED APPLICATIONS

This application is related to (219253-1, GEPL 2 00010) entitled “LUMINESCENT THERMOPLASTIC COMPOSITIONS AND ARTICLES WITH ENHANCED EDGE EMISSION”, filed on Dec. 22, 2006. This application is also related to (219895-1, GEPL 2 00012) entitled “LUMINESCENT SOLAR COLLECTOR”, filed on Dec. 22, 2006. These two related applications are hereby incorporated by reference in their entirety.

### BACKGROUND

The present disclosure relates generally to luminescent solar collectors. In particular, it relates to luminescent solar collectors whose viewing color or external appearance can be customized and retain a high level of solar energy collection.

Luminescent solar collectors (LSCs), or luminescent solar concentrators, are beneficial for capturing solar energy for use. An LSC usually comprises a sheet, generally a molded polymer, having a surface area. Dispersed within the sheet is a fluorescent dye. When the sheet is exposed to light (radiation energy), the dye absorbs the light and emits light at a different, longer wavelength. This light is then transported, via total internal reflection, to at least one edge of the sheet. The concentration of light from a large surface area to a smaller surface area (the edge) is also known as the “edge glow” effect. Due to this effect, the amount of light (i.e. energy) available at the edge is related to the total surface area of the sheet. A light energy converter, such as a silicon photocell, can be attached to at least one edge of the LSC to convert the light energy transmitted thereto into electricity.

The construction of such an LSC leads to several technical problems. For example, the final viewing color, or appearance, of the LSC is typically the color of the fluorescent dye. Such fluorescent dyes generally have a bright red color, which is aesthetically unpleasing and limits the application of LSCs. For example, the Lumogen® Red system outperforms quantum dots. It is also possible to make LSCs in other colors (like orange or yellow), but the options are limited due to the limited number of acceptable dyes.

Additionally, the typical lifetime requirement for an LSC is 15 years or longer. Over this time period, the LSC, especially the sheet, is exposed to the elements. A typical polymer, such as polycarbonate, used to make the sheet will weather over this time period. For example, the sheet will develop haze. High haze reduces the energy efficiency of the LSC.

Furthermore, the sheet generally must be made from a transparent polymer, such as polycarbonate (PC) or poly(methyl methacrylate) (PMMA) so the fluorescent dye can be exposed to the maximum amount of light. For some consumer applications, though, a translucent material is preferred. For example, skylights may be translucent. This translucence is similar to haze, though, and is also expected to reduce the energy efficiency of the LSC.

LSCs can also use fluorescent agents to concentrate light at the edge of the sheet. Only a small fraction of coloring agents are fluorescent, and only a fraction of those fluorescent coloring agents have the required properties for use in an LSC (e.g. high quantum yield and UV resistance). This limited range of fluorescent agents limits the possible viewing color of the final product. The term “viewing color” refers to the color of the LSC as seen by one looking at the LSC or its aesthetic color. The term does not refer to the wavelengths of the light on the edge of the LSC. It would be desirable to create an LSC with a customizable viewing color that also retains a high level of light concentration at the edge.

One means to change the viewing color of an LSC is to add colorants to the sheet. However, this drastically reduces the level of light concentration at the edge.

Multi-layer LSC systems are known, where fluorescent dyes are in separate layers. For example, U.S. Pat. No. 4,488,047 discloses such a system. These systems prevent the light emitted by one dye from being absorbed by another dye, but do not really expand the range of available colors. The viewing color is still restricted by the availability of suitable fluorescent dyes.

In U.S. Pat. No. 4,149,902, a layer containing a fluorescent dye is connected to a transparent layer. However, the transparent layer does not affect the viewing color of the LSC.

The use of opaque reflecting backings are also disclosed in, for example, U.S. Pat. Nos. 4,644,716 and 4,140,544.

There accordingly remains a need in the art for luminescent solar collectors which have improved appearance while maintaining the desired level of edge emission.

### BRIEF DESCRIPTION

Disclosed, in various embodiments, are luminescent solar collectors which have a customizable viewing color and a high level of light concentration at their edge or edges.

In an exemplary embodiment, the luminescent solar collector comprises a substrate and a light energy converter. The substrate comprises a first (or base) layer and a second (or covering) layer. The first and second layers are operatively connected to each other along an adjoining surface. The light energy converter is operatively connected to at least the first layer. The first layer comprises a first polymer and a fluorescent dye or quantum dot dispersed therein. The first layer is also configured in a manner to transmit the radiated light to the light energy converter. The second layer comprises a second polymer and a non-fluorescent dye or pigment. The non-fluorescent dye or pigment contributes to the customizable viewing color of the luminescent solar collector. In further embodiments, the non-fluorescent dye or pigment is the customizable viewing color of the luminescent solar collector. In further embodiments, the polymers are a polycarbonate or a polyester-polycarbonate.

In further embodiments, the fluorescent dye is a perylene or terrylene.

In further embodiments, the non-fluorescent dye or pigment is present in an amount of from about 0.0001 weight percent to about 1 weight percent, based on the total weight of the layer.

In other embodiments, the non-fluorescent layer further comprises a diffuser. The diffuser may be an organic diffuser. The diffuser may have a D₅₀ particle size of from about 1 micrometer to about 100 micrometers. The diffuser may be present in an amount of from about 0.0001 weight percent to about 0.2 weight percent, based on the total weight of the layer.

In another exemplary embodiment, the luminescent solar collector comprises a sheet and a photocell. The sheet comprises a fluorescent layer and a translucent layer operatively connected to the fluorescent layer along an adjoining surface. The translucent layer at least partially covers, and in some embodiments fully covers, the fluorescent layer. The photocell is operatively connected to at least the fluorescent layer. The fluorescent layer comprises a first polymer and a fluorescent dye or quantum dot dispersed therein. The translucent layer comprises a second polymer having a diffuser and a non-fluorescent dye or pigment dispersed within, wherein the non-fluorescent dye or pigment contributes to the customizable viewing color of the luminescent solar collector. In further embodiments, the sheet provides an edge emission of at least 90 W/m².

In a further exemplary embodiment, the luminescent solar collector has a preselected external color. The solar collector comprises a sheet (or panel) and a photocell. The sheet or panel comprises a first layer and a second layer at least partially covering the first layer. The first layer comprises a first polymer and a fluorescent dye or quantum dot. The translucent layer comprises a second polymer and a non-fluorescent dye or pigment dispersed therein. The sheet provides an edge emission of at least 50 W/m².

These and other non-limiting characteristics of the luminescent solar collectors of this disclosure are more particularly described below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is an elevated view of one embodiment of a luminescent solar collector of the present disclosure.

FIG. 2 is a cross-sectional view of the luminescent solar collector of FIG. 1.

### DETAILED DESCRIPTION

A more complete understanding of the components, processes and apparatuses disclosed herein can be obtained by reference to the accompanying drawings. These drawings are merely schematic representations based on convenience and the ease of demonstrating the present disclosure, and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

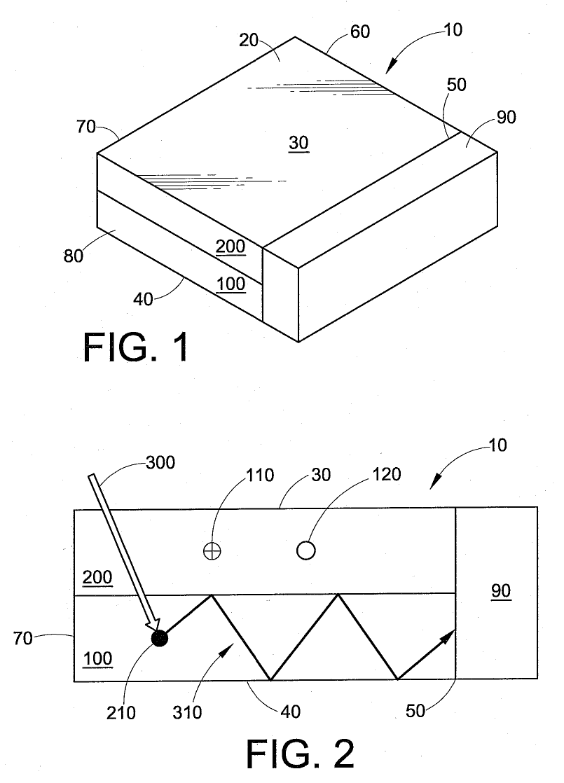

Referring to FIGS. 1 and 2, a luminescent solar collector (LSC) 10 comprises a large sheet 20. The sheet has two opposing surfaces 30, 40. The opposing surfaces 30, 40 are joined by at least one edge 50. For the sheet depicted, there are three additional connecting edges 60, 70, 80. A light energy converter, such as a photocell 90, is mounted or operatively connected along the at least one connecting edge 50 to convert the light to electricity. For example, the operative connection may be made by means including, but not limited to, glueing the converter to the edge, mounting it in a slit, or by positioning it along the edge. The sheet provides an edge emission of at least 50 W/m², including at least 70 W/m² and more particularly at least 90 W/m². Edge emission may be measured in watts per square meter (W/m²). It is measured where the operative connection to the light energy converter is made. In this embodiment, the edge emission is measured is at the connecting edge 50. The area in the denominator is that of the edge 50, not that of the surface 30.

The sheet 20 is a multi-layer structure comprising a first, or base, polymer layer 100 and a second, or covering, polymer layer 200. The first polymer layer 100 comprises a polymer and a fluorescent dye or quantum dot evenly dispersed therein. The second polymer layer 200 comprises a polymer and a non-fluorescent dye or pigment of a different color evenly dispersed therein. In other words, the non-fluorescent dye or pigment has a different viewing color from that of the fluorescent dye. The second polymer layer at least partially covers, and preferably fully covers, the first polymer layer. As used herein, the term “base” is not intended to refer to a particular physical orientation, but is merely used to distinguish the two polymer layers.

The sheet 20 is wide in two dimensions and thinner in the third dimension (its thickness). The opposing surfaces 30, 40 of the sheet 20 are generally parallel to each other, but need not be. It is also contemplated that the sheet 20 may be molded into various shapes. For example, the sheet may have the shape of a pyramidal frustum, a box, or as the surface of a hemisphere. The sheet may also vary in thickness. In particular embodiments, the sheet is planar. This shape is contemplated for use, for example, on the side or rooftop of a building, such as a house.

In FIG. 2, the covering polymer layer 200 comprises non-fluorescent dye or pigment particles 110. The polymer layer comprising the non-fluorescent dye or pigment may also comprise a diffuser 120. The base polymer layer 100 comprises fluorescent dye particles 210. As explained above, Light 300 is absorbed by the fluorescent dye particles 210. The particles 210 then emit light 310 with a Stokes shift (i.e. towards a higher wavelength). The emitted light, due to total internal reflection, is guided towards the edge 50 of the sheet where the photocell 90 is located. The other edges 60, 70, 80 may be coated, for example with a mirror coating to reflect light towards edge 50 as well. An opposing surface 40 may also be coated to reflect light as well.

Each polymer layer generally comprises a thermoplastic polymer. With respect to the polymers, as used herein, the term “hydrocarbyl” refers to a straight or branched chain, substituted or unsubstituted hydrocarbon group including aromatic and/or aliphatic groups; the term “alkyl” refers to a straight or branched chain monovalent hydrocarbon group; “alkylene” refers to a straight or branched chain divalent hydrocarbon group; “alkylidene” refers to a straight or branched chain divalent hydrocarbon group, with both valences on a single common carbon atom; “alkenyl” refers to a straight or branched chain monovalent hydrocarbon group having at least two carbons joined by a carbon-carbon double bond; “cycloalkyl” refers to a non-aromatic monovalent monocyclic or multicyclic hydrocarbon group having at least three carbon atoms, “cycloalkylene” refers to a non-aromatic alicyclic divalent hydrocarbon group having at least three carbon atoms, with at least one degree of unsaturation; “aryl” refers to an aromatic monovalent group containing only carbon in the aromatic ring or rings; “arylene” refers to an aromatic divalent group containing only carbon in the aromatic ring or rings; “alkylaryl” refers to an aryl group that has been substituted with an alkyl group as defined above, with 4-methylphenyl being an exemplary alkylaryl group; “arylalkyl” refers to an alkyl group that has been substituted with an aryl group as defined above, with benzyl being an exemplary arylalkyl group; “acyl” refers to a an alkyl group as defined above with the indicated number of carbon atoms attached through a carbonyl carbon bridge (—C(═O)—); “alkoxy” refers to an alkyl group as defined above with the indicated number of carbon atoms attached through an oxygen bridge (—O—); and “aryloxy” refers to an aryl group as defined above with the indicated number of carbon atoms attached through an oxygen bridge (—O—).

Unless otherwise indicated, each of the foregoing groups may be unsubstituted or substituted, provided that the substitution does not significantly adversely affect synthesis, stability, or use of the compound. The term “substituted” as used herein means that any one or more hydrogens on the designated atom or group are replaced with another group, provided that the designated atom's normal valence is not exceeded. When the substituent is oxo (i.e., ═O), then two hydrogens on the atom are replaced. Combinations of substituents and/or variables are permissible provided that the substitutions do not significantly adversely affect synthesis or use of the compound.

The polymers of the first and second layers 100, 200 each independently comprise a thermoplastic polymer, and they can be the same or different polymers. Types of thermoplastic polymers that are useful comprise polycarbonates, including homopolycarbonates, copolycarbonates, polyester-polycarbonates, and polysiloxane-polycarbonates; polyesters including poly(alkylene terephthalate); polyetherimides; polysiloxane-polyetherimides; polyphenylene ethers; polyolefins; addition polymers, including homopolymers and copolymers, especially homopolymers of alkenylaromatic compounds, such as polystyrenes, and copolymers of alkenylaromatic compounds, such as impact modified poly(alkenylaromatic) copolymers with ethylenically unsaturated nitriles, and poly(meth)acrylates.

The thermoplastic polymer can include a polycarbonate. As used herein, the terms “polycarbonate” and “polycarbonate resin” mean compositions having repeating structural carbonate units of the formula (1):

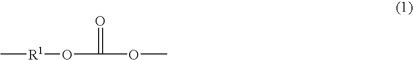

in which at least 60 percent of the total number of R¹ groups are aromatic organic radicals and the balance thereof are aliphatic, alicyclic, or aromatic radicals. In one embodiment, each R¹ is an aromatic organic radical, for example a radical of the formula (2):

-A¹-Y¹-A²- (2)

wherein each of A¹ and A² is a monocyclic divalent aryl radical and Y¹ is a bridging radical having one or two atoms that separate A¹ from A². In an exemplary embodiment, one atom separates A¹ from A². Illustrative non-limiting examples of radicals of this type are —O—, —S—, —S(O)—, —S(O)₂—, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y¹ may be a hydrocarbon group or a saturated hydrocarbon group such as methylene, cyclohexylidene, or isopropylidene.

Polycarbonates may be produced by the interfacial reaction of dihydroxy compounds having the formula HO—R¹—OH, which includes dihydroxy compounds of formula (3)

HO-A¹-Y¹-A²-OH (3)

wherein Y¹, A¹ and A² are as described above. Also included are bisphenol compounds of general formula (4):

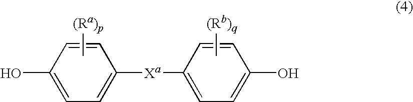

wherein R^{a} and R^{b} each represent a halogen atom or a monovalent hydrocarbon group and may be the same or different; p and q are each independently integers of 0 to 4; and X^{a} represents one of the groups of formula (5):

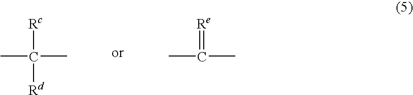

wherein R^{c} and R^{d} each independently represent a hydrogen atom or a monovalent linear or cyclic hydrocarbon group and R^{e} is a divalent hydrocarbon group.

In an embodiment, a heteroatom-containing cyclic alkylidene group comprises at least one heteroatom with a valency of 2 or greater, and at least two carbon atoms. Heteroatoms for use in the heteroatom-containing cyclic alkylidene group include —O—, —S—, and —N(Z)-, where Z is a substituent group selected from hydrogen, hydroxy, C₁₋₁₂ alkyl, C₁₋₁₂ alkoxy, or C₁₋₁₂ acyl. Where present, the cyclic alkylidene group or heteroatom-containing cyclic alkylidene group may have 3 to 20 atoms, and may be a single saturated or unsaturated ring, or fused polycyclic ring system wherein the fused rings are saturated, unsaturated, or aromatic.

Other bisphenols containing substituted or unsubstituted cyclohexane units can be used, for example bisphenols of formula (6):

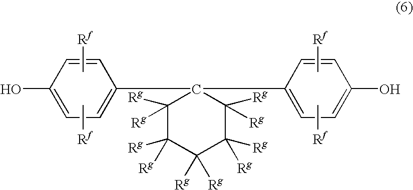

wherein each R^{f} is independently hydrogen, C₁₋₁₂ alkyl, or halogen; and each R^{g} is independently hydrogen or C₁₋₁₂ alkyl. The substituents may be aliphatic or aromatic, straight chain, cyclic, bicyclic, branched, saturated, or unsaturated. Such cyclohexane-containing bisphenols, for example the reaction product of two moles of a phenol with one mole of a hydrogenated isophorone, are useful for making polycarbonate polymers with high glass transition temperatures and high heat distortion temperatures. Cyclohexyl bisphenol containing polycarbonates, or a combination comprising at least one of the foregoing with other bisphenol polycarbonates, are supplied by Bayer Co. under the APEC® trade name.

Other useful dihydroxy compounds having the formula HO—R¹—OH include aromatic dihydroxy compounds of formula (7):

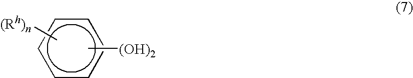

wherein each R^{h} is independently a halogen atom, a C₁₋₁₀ hydrocarbyl such as a C₁₋₁₀ alkyl group, a halogen substituted C₁₋₁₀ hydrocarbyl such as a halogen-substituted C₁₋₁₀ alkyl group, and n is 0 to 4. The halogen is usually bromine.

Exemplary dihydroxy compounds include the following: 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis(hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantine, (alpha,alpha′-bis(4-hydroxyphenyl)toluene, bis(4 hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene, 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, and the like, as well as combinations comprising at least one of the foregoing dihydroxy compounds.

Specific examples of bisphenol compounds that may be represented by formula (3) include 1,1-bis(4-hydroxyphenyl)methane, 1,1-bis(4-hydroxyphenyl)ethane, 2,2-bis(4-hydroxyphenyl)propane (hereinafter “bisphenol-A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl)n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (PPPBP), and 1,1-bis(4-hydroxy-3-methylphenyl)cyclohexane (DMBPC). Combinations comprising at least one of the foregoing dihydroxy compounds may also be used.

In a specific embodiment, the polycarbonate is a linear homopolymer derived from bisphenol-A, in which each of A¹ and A² is p-phenylene and Y¹ is isopropylidene. The polycarbonates may have an intrinsic viscosity, as determined in chloroform at 25° C., of from about 0.3 to about 1.5 deciliters per gram (dl/g), specifically from about 0.45 to about 1.0 dl/g. The polycarbonates may have a weight average molecular weight (Mw) of from about 10,000 to about 100,000, as measured by gel permeation chromatography (GPC) using a crosslinked styrene-divinyl benzene column, at a sample concentration of 1 milligram per milliliter, and as calibrated with polycarbonate standards.

In an embodiment, the polycarbonate has a melt volume flow rate (often abbreviated MVR). The MVR measures the rate at which a thermoplastic passes vertically through a capillary under a defined weight load. The MVR is measured in cubic cm per 10 minutes (cc/10 min). Polycarbonates useful for the formation of thin articles may have an MVR, measured at 300° C. under a load of 1.2 kg according to ASTM D1238-04, of from about 0.5 to about 80 cubic centimeters per 10 minutes (cc/10 min). In a specific embodiment, a useful polycarbonate composition has an MVR measured at 300° C. under a load of 1.2 kg according to ASTM D1238-04, of from about 0.5 to about 50 cc/10 min, specifically from about 0.5 to about 25 cc/10 min, and more specifically from about 1 to about 15 cc/10 min. Mixtures of polycarbonates of different flow properties may be used to achieve the overall desired flow property.

The polycarbonate may have a light transmittance greater than or equal to about 55%, specifically greater than or equal to about 60% and more specifically greater than or equal to about 70%, as measured using a molded article of 3.2±0.12 millimeters thickness and consisting of the polycarbonate, according to ASTM D1003-00. The polycarbonate may also have a haze less than or equal to about 5%, specifically less than or equal to about 4%, and most specifically less than or equal to about 3%, as measured using a molded article of 3.2±0.12 millimeters thickness and consisting of the polycarbonate, according to ASTM D1003-00.

“Polycarbonates” and “polycarbonate resins” as used herein further include homopolycarbonates, copolymers comprising different R¹ moieties in the carbonate (referred to herein as “copolycarbonates”), copolymers comprising carbonate units and other types of polymer units, such as ester units, polysiloxane units, and combinations comprising at least one of homopolycarbonates and copolycarbonates. As used herein, “combination” is inclusive of blends, mixtures, alloys, reaction products, and the like. A specific type of copolymer is a polyester carbonate, also known as a polyester-polycarbonate. Such copolymers further contain, in addition to recurring carbonate chain units of the formula (1), repeating units of formula (8):

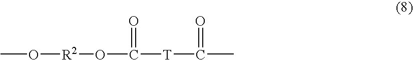

wherein R² is a divalent group derived from a dihydroxy compound, and may be, for example, a C₂₋₁₀ alkylene group, a C₆₋₂₀ alicyclic group, a C₆₋₂₀ aromatic group or a polyoxyalkylene group in which the alkylene groups contain 2 to about 6 carbon atoms, specifically 2, 3, or 4 carbon atoms; and T divalent group derived from a dicarboxylic acid, and may be, for example, a C₂₋₁₀ alkylene group, a C₆₋₂₀ alicyclic group, a C₆₋₂₀ alkyl aromatic group, or a C₆₋₂₀ aromatic group.

In an embodiment, R² is a C₂₋₃₀ alkylene group having a straight chain, branched chain, or cyclic (including polycyclic) structure. In another embodiment, R² is derived from an aromatic dihydroxy compound of formula (4) above. In another embodiment, R² is derived from an aromatic dihydroxy compound of formula (7) above.

Examples of aromatic dicarboxylic acids that may be used to prepare the polyester units include isophthalic or terephthalic acid, 1,2-di(p-carboxyphenyl)ethane, 4,4′-dicarboxydiphenyl ether, 4,4′-bisbenzoic acid, and combinations comprising at least one of the foregoing acids. Acids containing fused rings can also be present, such as in 1,4-, 1,5- or 2,6-naphthalenedicarboxylic acids. Specific dicarboxylic acids are terephthalic acid, isophthalic acid, naphthalene dicarboxylic acid, cyclohexane dicarboxylic acid, or combinations thereof. A specific dicarboxylic acid comprises a combination of isophthalic acid and terephthalic acid wherein the weight ratio of isophthalic acid to terephthalic acid is about 91:9 to about 2:98. In another specific embodiment, R² is a C₂₋₆ alkylene group and T is p-phenylene, m-phenylene, naphthalene, a divalent cycloaliphatic group, or a combination thereof. This class of polyester includes the poly(alkylene terephthalates).

In a specific embodiment, the polyester unit of a polyester-polycarbonate may be derived from the reaction of a combination of isophthalic and terephthalic diacids (or derivatives thereof) with resorcinol. In another specific embodiment, the polyester unit of a polyester-polycarbonate is derived from the reaction of a combination of isophthalic acid and terephthalic acid with bisphenol-A. In a specific embodiment, the polycarbonate units are derived from bisphenol-A.

Polycarbonates can be manufactured by processes such as interfacial polymerization and melt polymerization. Although the reaction conditions for interfacial polymerization may vary, an exemplary process generally involves dissolving or dispersing a dihydric phenol reactant in aqueous caustic soda or potash, adding the resulting mixture to a suitable water-immiscible solvent medium, and contacting the reactants with a carbonate precursor in the presence of a catalyst such as triethylamine or a phase transfer catalyst, under controlled pH conditions, e.g., about 8 to about 10. The most commonly used water immiscible solvents include methylene chloride, 1,2-dichloroethane, chlorobenzene, toluene, and the like.

Carbonate precursors include, for example, a carbonyl halide such as carbonyl bromide or carbonyl chloride, or a haloformate such as a bishaloformates of a dihydric phenol (e.g., the bischloroformates of bisphenol-A, hydroquinone, or the like) or a glycol (e.g., the bishaloformate of ethylene glycol, neopentyl glycol, polyethylene glycol, or the like). Combinations comprising at least one of the foregoing types of carbonate precursors may also be used. In an exemplary embodiment, an interfacial polymerization reaction to form carbonate linkages uses phosgene as a carbonate precursor, and is referred to as a phosgenation reaction.

Among the phase transfer catalysts that may be used are catalysts of the formula (R³)₄Q⁺X, wherein each R³ is the same or different, and is a C₁₋₁₀ alkyl group; Q is a nitrogen or phosphorus atom; and X is a halogen atom or a C₁₋₈ alkoxy group or C₆₋₁₈ aryloxy group. Useful phase transfer catalysts include, for example, [CH₃(CH₂)₃]₄NX, [CH₃(CH₂)₃]₄PX, [CH₃(CH₂)₅]₄NX, [CH₃(CH₂)₆]₄NX, [CH₃(CH₂)₄]₄NX, CH₃[CH₃(CH₂)₃]₃NX, and CH₃[CH₃(CH₂)₂]₃NX, wherein X is Cl⁻, Br⁻, a C₁₋₈ alkoxy group or a C₆₋₁₈ aryloxy group. An effective amount of a phase transfer catalyst may be about 0.1 to about 10 wt % based on the weight of bisphenol in the phosgenation mixture. In another embodiment an effective amount of phase transfer catalyst may be about 0.5 to about 2 wt % based on the weight of bisphenol in the phosgenation mixture.

Branched polycarbonate blocks may be prepared by adding a branching agent during polymerization. These branching agents include polyfunctional organic compounds containing at least three functional groups selected from hydroxyl, carboxyl, carboxylic anhydride, haloformyl, and mixtures of the foregoing functional groups. Specific examples include trimellitic acid, trimellitic anhydride, trimellitic trichloride, tris-p-hydroxy phenyl ethane, isatin-bis-phenol, tris-phenol TC (1,3,5-tris((p-hydroxyphenyl)isopropyl)benzene), tris-phenol PA (4(4(1,1-bis(p-hydroxyphenyl)-ethyl)alpha,alpha-dimethyl benzyl)phenol), 4-chloroformyl phthalic anhydride, trimesic acid, and benzophenone tetracarboxylic acid. The branching agents may be added at a level of about 0.05 to about 2.0 wt %. Mixtures comprising linear polycarbonates and branched polycarbonates may be used.

A chain stopper (also referred to as a capping agent) may be included during polymerization. The chain stopper controls molecular weight in the polycarbonate. Exemplary chain stoppers include certain mono-phenolic compounds, mono-carboxylic acid chlorides, and/or mono-chloroformates. Mono-phenolic chain stoppers are exemplified by monocyclic phenols such as phenol and C₁-C₂₂ alkyl-substituted phenols such as p-cumyl-phenol, resorcinol monobenzoate, and p- and tertiary-butyl phenol; and monoethers of diphenols, such as p-methoxyphenol. Alkyl-substituted phenols with branched chain alkyl substituents having 8 to 9 carbon atom may be specifically mentioned. Certain mono-phenolic UV absorbers may also be used as a capping agent, for example 4-substituted-2-hydroxybenzophenones and their derivatives, aryl salicylates, monoesters of diphenols such as resorcinol monobenzoate, 2-(2-hydroxyaryl)-benzotriazoles and their derivatives, 2-(2-hydroxyaryl)-1,3,5-triazines and their derivatives, and the like.

Mono-carboxylic acid chlorides may also be used as chain stoppers. These include monocyclic, mono-carboxylic acid chlorides such as benzoyl chloride, C₁-C₂₂ alkyl-substituted benzoyl chloride, toluoyl chloride, halogen-substituted benzoyl chloride, bromobenzoyl chloride, cinnamoyl chloride, 4-nadimidobenzoyl chloride, and combinations thereof; polycyclic, mono-carboxylic acid chlorides such as trimellitic anhydride chloride, and naphthoyl chloride; and combinations of monocyclic and polycyclic mono-carboxylic acid chlorides. Chlorides of aliphatic monocarboxylic acids with less than or equal to about 22 carbon atoms are useful. Functionalized chlorides of aliphatic monocarboxylic acids, such as acryloyl chloride and methacryloyl chloride, are also useful. Also useful are mono-chloroformates including monocyclic, mono-chloroformates, such as phenyl chloroformate, alkyl-substituted phenyl chloroformate, p-cumyl phenyl chloroformate, toluene chloroformate, and combinations thereof.

Alternatively, melt processes may be used to make the polycarbonates. Generally, in the melt polymerization process, polycarbonates may be prepared by co-reacting, in a molten state, the dihydroxy reactant(s) and a diaryl carbonate ester, such as diphenyl carbonate, in the presence of a transesterification catalyst in a Banbury® mixer, twin screw extruder, or the like to form a uniform dispersion. Volatile monohydric phenol is removed from the molten reactants by distillation and the polymer is isolated as a molten residue. A specifically useful melt process for making polycarbonates uses a diary carbonate ester having electron-withdrawing substituents on the aryls. Examples of specifically useful diaryl carbonate esters with electron withdrawing substituents include bis(4-nitrophenyl)carbonate, bis(2-chlorophenyl)carbonate, bis(4-chlorophenyl)carbonate, bis(methyl salicyl)carbonate, bis(4-methylcarboxylphenyl)carbonate, bis(2-acetylphenyl)carboxylate, bis(4-acetylphenyl)carboxylate, or a combination comprising at least one of the foregoing. In addition, transesterification catalysts for use may include phase transfer catalysts of formula (R³)₄Q⁺X above, wherein each R³, Q, and X are as defined above. Examples of transesterification catalysts include tetrabutylammonium hydroxide, methyltributylammonium hydroxide, tetrabutylammonium acetate, tetrabutylphosphonium hydroxide, tetrabutylphosphonium acetate, tetrabutylphosphonium phenolate, or a combination comprising at least one of the foregoing. Melt processes are generally carried out in a series of stirred tank reactors. The reaction can be carried out by either a batch mode or a continuous mode. The apparatus in which the reaction is carried out can be any suitable tank, tube, or column. Continuous processes usually involve the use of one or more continuous-stirred tank reactors (CSTRs) and one or more finishing reactors.

Polyester-polycarbonates may also be prepared by interfacial polymerization. Rather than utilizing the dicarboxylic acid per se, it is possible, and sometimes even preferred, to employ the reactive derivatives of the acid, such as the corresponding acid halides, in particular the acid dichlorides and the acid dibromides. Thus, for example instead of using isophthalic acid, terephthalic acid, or a combination comprising at least one of the foregoing, it is possible to employ isophthaloyl dichloride, terephthaloyl dichloride, and a combination comprising at least one of the foregoing.

In addition to the polycarbonates described above, combinations of the polycarbonate with other thermoplastic polymers, for example combinations of homopolycarbonates and/or polycarbonate copolymers with polyesters, may be used. Useful polyesters may include, for example, polyesters having repeating units of formula (8), which include poly(alkylene dicarboxylates), liquid crystalline polyesters, and polyester copolymers. The polyesters described herein are generally completely miscible with the polycarbonates when blended.

The polyesters may be obtained by interfacial polymerization or melt-process condensation as described above, by solution phase condensation, or by transesterification polymerization wherein, for example, a dialkyl ester such as dimethyl terephthalate may be transesterified with ethylene glycol using acid catalysis, to generate poly(ethylene terephthalate). It is possible to use a branched polyester in which a branching agent, for example, a glycol having three or more hydroxyl groups or a trifunctional or multifunctional carboxylic acid has been incorporated. Furthermore, it is sometime desirable to have various concentrations of acid and hydroxyl end groups on the polyester, depending on the ultimate end use of the polymer.

Useful polyesters may include aromatic polyesters, poly(alkylene esters) including poly(alkylene arylates), and poly(cycloalkylene diesters). Aromatic polyesters may have a polyester structure according to formula (8), wherein D and T are each aromatic groups as described hereinabove. In an embodiment, useful aromatic polyesters may include, for example, poly(isophthalate-terephthalate-resorcinol) esters, poly(isophthalate-terephthalate-bisphenol-A) esters, poly[(isophthalate-terephthalate-resorcinol) ester-co-(isophthalate-terephthalate-bisphenol-A)]ester, or a combination comprising at least one of these. Also contemplated are aromatic polyesters with a minor amount, e.g., about 0.5 to about 10 wt %, based on the total weight of the polyester, of units derived from an aliphatic diacid and/or an aliphatic polyol to make copolyesters. Poly(alkylene arylates) may have a polyester structure according to formula (8), wherein T comprises groups derived from aromatic dicarboxylates, cycloaliphatic dicarboxylic acids, or derivatives thereof. Examples of specifically useful T groups include 1,2-, 1,3-, and 1,4-phenylene; 1,4- and 1,5-naphthylenes; cis- or trans-1,4-cyclohexylene; and the like. Specifically, where T is 1,4-phenylene, the poly(alkylene arylate) is a poly(alkylene terephthalate). In addition, for poly(alkylene arylate), specifically useful alkylene groups D include, for example, ethylene, 1,4-butylene, and bis-(alkylene-disubstituted cyclohexane) including cis- and/or trans-1,4-(cyclohexylene)dimethylene. Examples of poly(alkylene terephthalates) include poly(ethylene terephthalate) (PET), poly(1,4-butylene terephthalate) (PBT), and poly(propylene terephthalate) (PPT). Also useful are poly(alkylene naphthoates), such as poly(ethylene naphthanoate) (PEN), and poly(butylene naphthanoate) (PBN). A useful poly(cycloalkylene diester) is poly(cyclohexanedimethylene terephthalate) (PCT). Combinations comprising at least one of the foregoing polyesters may also be used.

Copolymers comprising alkylene terephthalate repeating ester units with other ester groups may also be useful. Useful ester units may include different alkylene terephthalate units, which can be present in the polymer chain as individual units, or as blocks of poly(alkylene terephthalates). Specific examples of such copolymers include poly(cyclohexanedimethylene terephthalate)-co-poly(ethylene terephthalate), abbreviated as PETG where the polymer comprises greater than or equal to 50 mol % of poly(ethylene terephthalate), and abbreviated as PCTG where the polymer comprises greater than 50 mol % of poly(1,4-cyclohexanedimethylene terephthalate).

Poly(cycloalkylene diester)s may also include poly(alkylene cyclohexanedicarboxylate)s. Of these, a specific example is poly(1,4-cyclohexane-dimethanol-1,4-cyclohexanedicarboxylate) (PCCD), having recurring units of formula (9):

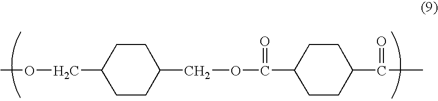

wherein, as described using formula (8), R² is a 1,4-cyclohexanedimethylene group derived from 1,4-cyclohexanedimethanol, and T is a cyclohexane ring derived from cyclohexanedicarboxylate or a chemical equivalent thereof, and may comprise the cis-isomer, the trans-isomer, or a combination comprising at least one of the foregoing isomers.

The polyester-polycarbonates may have a weight-averaged molecular weight (M_{w}) of from about 1,500 to about 100,000, specifically from about 1,700 to about 50,000, and more specifically from about 2,000 to about 40,000. Molecular weight determinations are performed using gel permeation chromatography (GPC), using a crosslinked styrene-divinylbenzene column and calibrated to polycarbonate references. Samples are prepared at a concentration of about 1 mg/ml, and are eluted at a flow rate of about 1.0 ml/min.

Where used, it is desirable for a polyester-polycarbonate to have an MVR of about 5 to about 150 cc/10 min., specifically about 7 to about 125 cc/10 min, more specifically about 9 to about 110 cc/10 min, and still more specifically about 10 to about 100 cc/10 min., measured at 300° C. and a load of 1.2 kilograms according to ASTM D1238-04. Commercial polyester blends with polycarbonate are marketed under the trade name XYLEX®, including for example XYLEX® X7300, and commercial polyester-polycarbonates are marketed under the tradename LEXAN® SLX polymers, including for example LEXAN® SLX-9000, and are available from GE Plastics.

The thermoplastic polymer may also comprise a polysiloxane-polycarbonate copolymer, also referred to as a polysiloxane-polycarbonate. The polysiloxane (also referred to herein as “polydiorganosiloxane”) blocks of the copolymer comprise repeating siloxane units (also referred to herein as “diorganosiloxane units”) of formula (10):

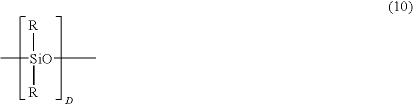

wherein each occurrence of R is same or different, and is a C₁₋₁₃ monovalent organic radical. For example, R may independently be a C₁-C₁₃ alkyl group, C₁-C₁₃ alkoxy group, C₂-C₁₃ alkenyl group, C₂-C₁₃ alkenyloxy group, C₃-C₆ cycloalkyl group, C₃-C₆ cycloalkoxy group, C₆-C₁₄ aryl group, C₆-C₁₀ aryloxy group, C₇-C₁₃ arylalkyl group, C₇-C₁₃ arylalkoxy group, C₇-C₁₃ alkylaryl group, or C₇-C₁₃ alkylaryloxy group. The foregoing groups may be fully or partially halogenated with fluorine, chlorine, bromine, or iodine, or a combination thereof. Combinations of the foregoing R groups may be used in the same copolymer.

The value of D in formula (10) may vary widely depending on the type and relative amount of each component in the thermoplastic polymer, the desired properties of the polymer, and like considerations. Generally, D may have an average value of 2 to 1,000, specifically 2 to 500, and more specifically 5 to 100. In one embodiment, D has an average value of 10 to 75, and in still another embodiment, D has an average value of 40 to 60. Where D is of a lower value, e.g., less than 40, it may be desirable to use a relatively larger amount of the polycarbonate-polysiloxane copolymer. Conversely, where D is of a higher value, e.g., greater than 40, it may be necessary to use a relatively lower amount of the polycarbonate-polysiloxane copolymer.

A combination of a first and a second (or more) polysiloxane-polycarbonate copolymer may be used, wherein the average value of D of the first copolymer is less than the average value of D of the second copolymer.

In one embodiment, the polydiorganosiloxane blocks are provided by repeating structural units of formula (11):

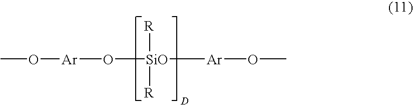

wherein D is as defined above; each R may independently be the same or different, and is as defined above; and each Ar may independently be the same or different, and is a substituted or unsubstituted C₆-C₃₀ arylene radical, wherein the bonds are directly connected to an aromatic moiety. Useful Ar groups in formula (11) may be derived from a C₆-C₃₀ dihydroxyarylene compound, for example a dihydroxyarylene compound of formula (3), (4), or (7) above. Combinations comprising at least one of the foregoing dihydroxyarylene compounds may also be used. Specific examples of dihydroxyarylene compounds are 1,1-bis(4-hydroxyphenyl)methane, 1,1-bis(4-hydroxyphenyl)ethane, 2,2-bis(4-hydroxyphenyl)propane, 2,2-bis(4-hydroxyphenyl)butane, 2,2-bis(4-hydroxyphenyl)octane, 1,1-bis(4-hydroxyphenyl)propane, 1,1-bis(4-hydroxyphenyl)n-butane, 2,2-bis(4-hydroxy-1-methylphenyl)propane, 1,1-bis(4-hydroxyphenyl)cyclohexane, bis(4-hydroxyphenyl sulphide), and 1,1-bis(4-hydroxy-t-butylphenyl)propane. Combinations comprising at least one of the foregoing dihydroxy compounds may also be used.

Units of formula (11) may be derived from the corresponding dihydroxy compound of formula (12):

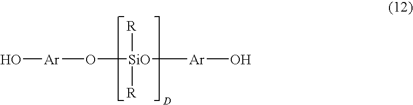

wherein R, Ar, and D are as described above. Compounds of formula (12) may be obtained by the reaction of a dihydroxyarylene compound with, for example, an alpha,omega-bisacetoxypolydiorangonosiloxane under phase transfer conditions.

In another embodiment, polydiorganosiloxane blocks comprise units of formula (13):

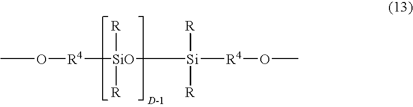

wherein R and D are as described above, and each occurrence of R⁴ is independently a divalent C₁-C₃₀ alkylene, and wherein the polymerized polysiloxane unit is the reaction residue of its corresponding dihydroxy compound. In a specific embodiment, the polydiorganosiloxane blocks are provided by repeating structural units of formula (14):

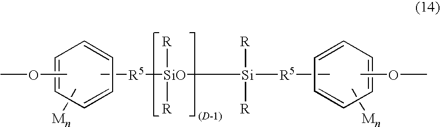

wherein R and D are as defined above. Each R⁵ in formula (14) is independently a divalent C₂-C₈ aliphatic group. Each M in formula (14) may be the same or different, and may be a halogen, cyano, nitro, C₁-C₈ alkylthio, C₁-C₈ alkyl, C₁-C₈ alkoxy, C₂-C₈ alkenyl, C₂-C₈ alkenyloxy group, C₃-C₈ cycloalkyl, C₃-C₈ cycloalkoxy, C₆-C₁₀ aryl, C₆-C₁₀ aryloxy, C₇-C₁₂ arylalkyl, C₇-C₁₂ arylalkoxy, C₇-C₁₂ alkylaryl, or C₇-C₁₂ alkylaryloxy, wherein each n is independently 0, 1, 2, 3, or 4.

In one embodiment, M is bromo or chloro, an alkyl group such as methyl, ethyl, or propyl, an alkoxy group such as methoxy, ethoxy, or propoxy, or an aryl group such as phenyl, chlorophenyl, or tolyl; R⁵ is a dimethylene, trimethylene or tetramethylene group; and R is a C₁₋₈ alkyl, haloalkyl such as trifluoropropyl, cyanoalkyl, or aryl such as phenyl, chlorophenyl or tolyl. In another embodiment, R is methyl, or a mixture of methyl and trifluoropropyl, or a mixture of methyl and phenyl. In still another embodiment, M is methoxy, n is one, R⁵ is a divalent C₁-C₃ aliphatic group, and R is methyl.

Units of formula (14) may be derived from the corresponding dihydroxy polydiorganosiloxane (15):

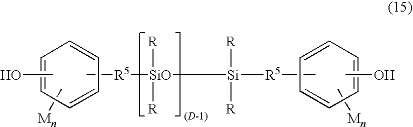

wherein R, D, M, R⁵, and n are as described above. Such dihydroxy polysiloxanes can be made by effecting a platinum catalyzed addition between a siloxane hydride of formula (16):

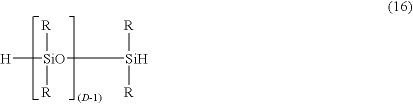

wherein R and D are as previously defined, and an aliphatically unsaturated monohydric phenol. Useful aliphatically unsaturated monohydric phenols included, for example, eugenol, 2-allylphenol, 4-allyl-2-methylphenol, 4-allyl-2-phenylphenol, 4-allyl-2-bromophenol, 4-allyl-2-t-butoxyphenol, 4-phenyl-2-phenylphenol, 2-methyl-4-propylphenol, 2-allyl-4,6-dimethylphenol, 2-allyl-4-bromo-6-methylphenol, 2-allyl-6-methoxy-4-methylphenol and 2-allyl-4,6-dimethylphenol. Mixtures comprising at least one of the foregoing may also be used.

In an embodiment, the polysiloxane-polycarbonate may comprise polysiloxane units, and carbonate units derived from bisphenol-A, e.g., the dihydroxy compound of formula (3) in which each of A¹ and A² is p-phenylene and Y¹ is isopropylidene. Polysiloxane-polycarbonates may have a weight average molecular weight of 2,000 to 100,000, specifically 5,000 to 50,000 as measured by gel permeation chromatography using a crosslinked styrene-divinyl benzene column, at a sample concentration of 1 milligram per milliliter, and as calibrated with polycarbonate standards.

The polysiloxane-polycarbonate can have a melt volume flow rate, measured at 300° C. under a load of 1.2 kg, of 1 to 50 cubic centimeters per 10 minutes (cc/10 min), specifically 2 to 30 cc/10 min. Mixtures of polysiloxane-polycarbonates of different flow properties may be used to achieve the overall desired flow property. In an embodiment, exemplary polysiloxane-polycarbonates are marketed under the trade name LEXAN® EXL polycarbonates, available from GE Plastics.

In specific embodiments, the thermoplastic polymer of the first and second layers is a polycarbonate For example, the thermoplastic polymer may be LEXAN® polycarbonate available from General Electric Company. Other suitable thermoplastic polymers include, for example, poly(methyl methacrylate) (PMMA) such as those offered by Rohm GmbH & Co., clear acrylonitrile-butadiene-styrene (ABS) such as that sold by BASF, clear NORYL® available from General Electric Company, and XYLEX® made by General Electric Company.

The thermoplastic polymer may also be a homopolymer or a copolymer. In particular, the thermoplastic polymer may be a polyester carbonate, also known as polyester-polycarbonate. In a particular embodiment, the polyester unit may be derived from the reaction of isophthalic acid, terephthalic acid, and resorcinol (also known as an ITR resin). Such polyester-polycarbonates are available as LEXAN® SLX from General Electric Company. The polyester and polycarbonate may be used in a molar ratio of from about 10:90 to about 90:10 or more particularly from about 30:70 to about 70:30, depending on the properties desired. The polyester-polycarbonates may have a weight average molecular weight of from about 1,500 to about 100,000 or more particularly from about 2,000 to about 40,000.

The thermoplastic polymer may also be a polysiloxane-polycarbonate. Such polysiloxane-polycarbonates are available as LEXAN® EXL from General Electric Company. The polysiloxane and polycarbonate may be used in a molar ratio of from about 2:98 to about 30:70 or more particularly from about 3:97 to about 25:75, depending on the properties desired. The polyester-polycarbonates may have a weight average molecular weight of from about 2,000 to about 100,000 or more particularly from about 5,000 to about 50,000.

One layer 100 of the sheet 20 of the luminescent solar collector 10 comprises a fluorescent dye. The term “fluorescent” refers to the emission of light by the dye, after absorbing light radiation, at a defined wavelength (due to the Stokes shift). By comparison, a non-fluorescent dye does not absorb the energy and re-emit it at a defined wavelength, but as heat (i.e. a broad band of radiation). Any fluorescent dye can be used that does not significantly adversely affect the desired properties of the layer it is in.

Exemplary dyes include the daylight fluorescent-type dyes that belong to the dye families known as rhodamines, fluoresceins, coumarins, naphthalimides, benzoxanthenes, perylenes, pyrenes, acridines, or a combination comprising at least one of the foregoing. Examples include luminescent dyes such as 7-amino-4-methylcoumarin; 3-(2′-benzothiazolyl)-7-diethylaminocoumarin; 2-(4-biphenylyl)-5-(4-t-butylphenyl)-1,3,4-oxadiazole; 2,5-bis-(4-biphenylyl)-oxazole; 2,2′-dimethyl-p-quaterphenyl; 2,2-dimethyl-p-terphenyl; 3,5,3″″,5″″-tetra-t-butyl-p-quinquephenyl; 2,5-diphenylfuran; 2,5-diphenyloxazole; 4,4′-diphenylstilbene; 4-dicyanomethylene-2-methyl-6-(p-dimethylaminostyryl)-4H-pyran; 1,1′-diethyl-2,2′-carbocyanine iodide; 3,3′-diethyl-4,4′,5,5′-dibenzothiatricarbocyanine iodide; 7-dimethylamino-1-methyl-4-methoxy-8-azaquinolone-2; 7-dimethylamino-4-methylquinolone-2; 2-(4-(4-dimethylaminophenyl)-1,3-butadienyl)-3-ethylbenzothiazolium perchlorate; 3-diethylamino-7-diethyliminophenoxazonium perchlorate; 2-(1-naphthyl)-5-phenyloxazole; 2,2′-p-phenylen-bis(5-phenyloxazole); rhodamine 700; rhodamine 800; pyrene; chrysene; rubrene; coronene, or the like; perylene dyes such as those based on imido derivatives of perylene tetracarboxylic acid; or combinations comprising at least one of the foregoing dyes. Suppliers of fluorescent colorants include Radiant Color Company (Richmond, Calif.), Day-Glo Color Corp. (Cleveland, Ohio), Sun Chemical Co. (Cincinnati, Ohio). Sinloihi Co. Ltd. (Tokyo, Japan), Swada (London, England), Mikuni Color Works Ltd. (Himeji, Japan), Matsui International Co, Inc (Japan), Nippon Keiko Color Company (Japan). Specifically useful fluorescent dyes include those available under the following tradenames: Diaresin® dyes from Mitsubishi Chemical (Japan); Lumogen® dyes from BASF (Germany), Irgalite® and Maxilon® dyes from Ciba Specialty Chemicals (Germany), Macrolex® dyes from Lanxess (Germany), and Hostasol® dyes from Clariant. Typical commercially available fluorescent dyes of the above types include amino phthalate dyes such as Rhodamine BDC (C.I. 45,170), Rhodamine 6GDN extra (C.I. 45,160; Red 480), Rhodamine F5G (Red 482), Rhodamine FB (Red 540), and Rhodamine F3B (C.I. 45,175); naphthalimide derivatives such as Lumogen® F Blue 650; perylene derivatives such as Lumogen® F Red 305; Lumogen® F Yellow 083; Lumogen® F Violet 570; Lumogen® F Green 850; Macrolex® Fluorescent Yellow 10GN (C.I. Solvent Yellow 160:1); Macrolex® Red G; Irgalite® Violet M, Maxilon® Brilliant Flavine 10 GFF, Maxilon® Black FBL-01, Maxilon® Black RM-01, Maxilon® Blue 5G, Maxilon® Blue 5G-01, Maxilon® Blue GRL/Pearl, Maxilon® Blue GRL Granulated, Maxilon® Blue GRL E, Maxilon® Blue M-G, Maxilon® Blue TRL Liquid, Maxilon® Golden Yellow GL Pearls, Maxilon® Navy FRL-02, Maxilon® Red GRL-01 Pearl, Maxilon® Red GRL-E, Maxilon® Red GRL Pearls, Maxilon® Red M-4GL, Maxilon® Yellow M-3RL, and Maxilon® Yellow M-4GL; Hostasol® Red 5B (Vat Red 41), Hostasol® Red GG (Solvent Orange 63), and Hostasol® Yellow 3G (Solvent Yellow 98); Fluorescent yellow F6PN and Yellow Y toner; Fluorescent Red 66; fluorescein; and 9-aminoacridine. A combination comprising at least one of the foregoing fluorescent dyes may be used. In an exemplary embodiment, fluorescent dyes useful herein include Lumogen® F Blue 650, Lumogen® Red 305, and Macrolex® Fluorescent Yellow 10GN. It will be understood that numerous fluorescent dyes are available commercially and are useful herein, and that therefore the foregoing list of fluorescent dyes should be considered exemplary, and not limiting to the dyes disclosed hereinabove. The fluorescent dye is generally dispersed completely throughout the layer.

In an embodiment, the fluorescent dyes may be covalently bonded to a polymeric backbone to provide a polymer-supported fluorescent dye, and may also be referred to as dye conjugates. Such dye conjugates are useful to provide a fluorescent dye that is predispersed, i.e., one that is distributed throughout the polymer and which can provide a maximum fluorescence due to the more uniform dispersion. Dyes which are not so dispersed may aggregate or clump, and thereby decrease the effective loading of the dye based on the desired linear relationship between the fluorescent intensity and dye loading. Further, aromatic dyes, such as for example pyrene-based dyes, can when held proximate to one another form dimeric complexes (“excimers”) that can have a shifted absorbance and/or fluorescent emission wavelength and intensity relative to the parent non-dimeric dye. Distributing the fluorescent dye along a polymer backbone by covalent bonding can, in addition to the advantages enumerated hereinabove, be used as a method to reduce or eliminate excimer formation. Fluorescent dyes that are useful for preparing dye conjugates include those having reactive functional groups capable of forming a covalent bond with a useful monomer or functional polymer or functional resin. Exemplary reactive groups provided by the fluorescent dye include phenolic hydroxy, aliphatic hydroxy, aromatic amine, aliphatic amine, thiols, carboxylic acid, and carboxylate esters. It will be understood that the foregoing list of reactive groups is meant to be exemplary, and should not be limited thereto.

Further functionalization of these functional fluorescent dyes, to provide reactive derivatives, can further increase the reactive usefulness of the fluorescent dye so functionalized. Reactive substituents can be formed by covalently reacting functional agents such as, for example, reactive derivatives of (meth)acrylic acid such as (meth)acryloyl chloride; carbonyl dihalides such as phosgene; thiocarbonyl dihalides such as thiophosgene; maleic anhydride; chloroformates including alkyl, aryl, or aralkyl chloroformates, epichlorohydrin; or the like; to the above functional dyes to provide suitable reactive groups. In an exemplary embodiment, useful functionalized fluorescent dyes include functional groups such as (meth)acrylates, (meth)acrylamides, N-hydroxysuccinimidyl (NHS) esters, isocyanates, isothiocyanates, maleimides, chloroformates, anhydrides, mixed anhydrides, epoxides, and the like. Polymeric backbone supports for such dyes can include linear polymers, crosslinked polymers, dendrimers, graft copolymers, block copolymers including two or more blocks, end group modified polymers, hyperbranched copolymers, telechelic oligomers, or the like. Useful backbone polymers typically includes poly(meth)acrylic homopolymers or copolymers including poly(meth)acrylates, poly(meth)acrylamides, and the like; poly(vinyl aromatic) polymers and copolymers, including polystyrenes, copolymers thereof, and the like; polyvinyl polymers such as poly(vinyl acetate) or poly(vinyl alcohol), copolymers thereof, and the like; poly(alkylene oxide)s, copolymers thereof, and the like. In an embodiment, the functionalized fluorescent dye is attached to a polymer by reaction of the functional dye with a complementarily functionalized polymer. In another embodiment, the functionalized fluorescent dye having a polymerizable end group such as a (meth)acrylate or epoxide can be copolymerized with other monomers or reactive oligomers to provide a polymer-supported fluorescent dye. Other polymeric backbones that may be used as backbone support include polyesters, polycarbonates, polyimides, carbohydrate materials including substituted or unsubstituted cellulosic materials, polysaccharides, dextrins, aminosugars, and the like; proteins; or a combination comprising at least one of the foregoing polymers. In an embodiment, the polymer-supported fluorescent dyes include fluorescent dyes incorporated into the polymeric backbone in an amount of 0.005 to 5 wt %, based on the total weight of the fluorescent dye and polymer backbone.

A fluorescent brightener can also be included with the fluorescent dye. Fluorescent brighteners include fluorescent compounds which, when combined with a dye having relatively low fluorescence, act to increase the intensity of the fluorescent emissions from the dye combination. In an embodiment, a fluorescent brightener is used in combination with a blue fluorescent dye. Exemplary fluorescent brighteners include those marketed under the tradename Uvitex® and available from Ciba Specialty Chemicals, or DIPHYL® and BLANKOPHOR® available from Lanxess. In a specific exemplary embodiment, a useful combination of a blue dye and fluorescent brightener includes Uvitex® OB, available from Ciba Specialty Chemicals, as fluorescent brightener. It will be understood that the foregoing fluorescent brightener is exemplary and should not be considered as limiting thereto. When used, a fluorescent brightener may be included in an amount of from about 0.005 weight percent to about 25 weight percent, specifically from about 0.01 weight percent to about 20 weight percent, and more specifically from about 0.015 weight percent to about 15 weight percent, based on the total weight of the layer it is in.

Perylene diimides have high quantum yields and good weatherability. In specific embodiments, at least one dye based on a perylene or terrylene structure, or derivative thereof, is used. Perylene and terrylene structures are shown below:

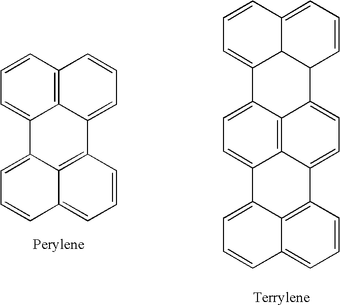

The fluorescent dye preferably has a wavelength of maximum absorbance greater than 430 nanometers. This is the highest energy area of the solar spectrum, so has the greatest amount of energy to be captured. The fluorescent dye preferably absorbs wavelengths over a large portion of the visible and near infrared spectrum (or from about 400 nanometers to about 950 nanometers). Perylene diimides, such as Lumogen® F Red 305, available from BASF, are especially suitable for use.

The fluorescent dye is used in coloring amounts of from about 0.001 weight percent to about 1 weight percent, particularly from about 0.005 weight percent to about 0.1 weight percent, and more particularly from about 0.02 weight percent to about 0.05 weight percent, based on the total weight of the polymer layer it is contained in.

Fluorescent dyes are distinguished from fluorescent pigments in that dyes are organic compounds whereas pigments are inorganic compounds. Fluorescent pigments are not equivalent to fluorescent dyes and cannot be used to replace them.

Quantum dots are nanostructures, having particle sizes in the range of from about 2 nanometers to about 100 nanometers. They may be inorganic compounds, but they are suitable for coloring the thermoplastic composition. Quantum dots may be considered interchangeable with fluorescent dyes. However, to be clear, pigments having particle sizes in the micrometer range are still unsuitable.

Whether a fluorescent dye or quantum dot is used, it should have a high quantum yield. This refers to the amount of light energy that is re-emitted as light. The light energy that is not re-emitted as light is usually converted into heat, which itself will break down the dye. In specific embodiments, the fluorescent dye has a quantum yield greater than 75%. In other specific embodiments, the fluorescent dye has a quantum yield greater than 80%. In other specific embodiments, the fluorescent dye has a quantum yield greater than 90%.

The other layer 200 of the sheet comprises a non-fluorescent dye or pigment as a colorant. Any non-fluorescent dye or pigment can be used, provided it does not significantly adversely affect the desired properties of the polymer layer. In an embodiment, the non-fluorescent dye has a wavelength of maximum absorbance greater than 400 nanometers. At this range, the non-fluorescent dye does not serve as an ultraviolet light absorber.

Useful dyes include, for example, coumarin dyes; lanthanide complexes; hydrocarbon and substituted hydrocarbon dyes; polycyclic aromatic hydrocarbon dyes; scintillation dyes; aryl- or heteroaryl-substituted polyolefin dyes; carbocyanine dyes; indanthrone dyes; phthalocyanine dyes; oxazine dyes; carbostyryl dyes; napthalenetetracarboxylic acid dyes; porphyrin dyes; bis(styryl)biphenyl dyes; acridine dyes; anthraquinone dyes; cyanine dyes; methine dyes; arylmethane dyes; azo dyes; indigoid dyes, thioindigoid dyes, diazonium dyes; nitro dyes; quinone imine dyes; aminoketone dyes; tetrazolium dyes; thiazole dyes; perylene dyes, perinone dyes; bis-benzoxazolylthiophene (BBOT); triarylmethane dyes; xanthene dyes; thioxanthene dyes; naphthalimide dyes; lactone dyes; and the like; and a combination comprising at least one of the foregoing non-fluorescent dyes. Oil-soluble dyes are specifically useful. Other exemplary commercially available dyes include those marketed under the Aizen Sot® trade name and made by Hodogaya Chemical Co., Ltd.; dyes marketed under the Sudan® trade name, made by BASF Corp.; dyes marketed under the Diaresin® trade name and made by Mitsubishi Chemical Industries, Ltd.; dyes made under the Oil Color® trade name by Orient Chemical Industries, Ltd.; dyes made under the Sumiplast® trade name by Sumitomo Chemical Co., Ltd.; dyes made under the Kayaron® and Kayaset tradenames, made by Nippon Kayaku Co., Ltd.; dyes made under the Levafix® tradenames, available from Bayer; dyes made under the Procion® tradename, available from ICI; Dyes under the Cibacron® and Lanasol® tradenames, available from Ciba-Geigy; dyes made under the Basilen® tradename, available from BASF; dyes made under the Sumifix® tradename, available from Sumitomo Chemical Company; dyes made under the Intracron® tradename, available from Crompton and Knowles, Dyes and Chemicals Division; dyes made under the Duasyn® tradename, available from Hoechst; and dyes available from Sigma Chemical Company or Aldrich Chemical Company Incorporated, and the like. A combination comprising at least one of the foregoing dyes may be used.

Additional exemplary dyes include the FLEXO®, Auramine®, Chrysoidine®, Victoria®, Crystal®, and Spirit® dyes available from BASF Corp. distributor in Clifton, N.J., which include diarylmethane dyes such as Yellow 105 Low-Dusting (also known as Basic Yellow 2203), Yellow 110 (Auramine FA), Yellow 110 Low-Dusting (Auramine FA-NS); Yellow 112 (Auramine FWA), and Yellow 112 Low-Dusting (Auramine FWA-NS); azomethine dyes such as Yellow 11B Low-Dusting; monoazo dyes such as Orange 204 (Chrysoidine FL); triarylmethane dyes including Violet 600 (Methyl Violet FN), Violet 615 (Crystal Violet FN), Blue 630 (Victoria blue FBR), Blue 838 (Victoria Pure Blue FBO), Blue 640 (Victoria Blue F8), Blue 640 Low-Dusting (Victoria Blue FB-NS), Blue 680 (Victoria Pure Blue FGA), and Blue 810 (Victoria Cyan FBG); and mixed dyes such as Green 990 (Spirit Green IY Conc.), Black XII (Flexo Black GL) and Blue 680 (Victoria Pure Blue FGA) also known as Basic Blue 81 C.I.

The non-fluorescent dye or pigment is used in coloring amounts of from about 0.001 weight percent to about 1 weight percent, particularly from about 0.005 weight percent to about 0.1 weight percent, and more particularly from about 0.02 weight percent to about 0.05 weight percent, based on the total weight of the polymer layer it is contained in.

The layer comprising a non-fluorescent dye or pigment may further comprise a diffuser. The diffuser scatters light passing through the polymer layer. The diffuser is generally added to the polymer layer in particle form. The particles may be regular or irregular in shape. In specific embodiments, the diffuser has a D50 particle size of from about 1 micrometer to about 100 micrometers. In further embodiments, the D₅₀ particle size is from about 20 microns to about 80 microns, specifically from about 30 microns to about 60 microns. The particles may be randomly distributed or aligned deterministically. The diffuser may be included in an amount of from about 0.0001 weight percent to 0.2 weight percent, based on the total weight of the polymer layer. In further embodiments, the diffuser is included in an amount of from about 0.005 weight percent to about 0.5 weight percent, specifically from about 0.005 weight percent to about 0.2 weight percent. In specific embodiments, the diffuser is an organic diffuser. Suitable organic light diffusers include poly(acrylates); poly(alkyl methacrylates), for example poly(methyl methacrylate) (PMMA)) and cross-linked PMMA available under the trade name MBX® from Sekisui; poly(tetrafluoroethylene) (PTFE); silicones, for example hydrolyzed poly(alkyl trialkoxysilanes) available under the trade name TOSPEARL® from GE Silicones; and mixtures comprising at least one of the foregoing organic materials, wherein the alkyl groups have from one to about twelve carbon atoms.

Organic or inorganic pigments may be used in the layer comprising a non-fluorescent dye or pigment as long as light still passes through this layer into the layer comprising a fluorescent dye. In particular, pigments may be used as the diffuser. However, too much inorganic pigment will opacify the layer, reducing the amount of light passing into the layer comprising a fluorescent dye.

Due to the possible use of a diffuser, the polymer layer comprising the non-fluorescent dye or pigment can be either transparent or translucent. The term “translucent” means that light can pass through the layer, but the light is diffused. It should also be noted that the relative arrangement of the polymer layers (the fluorescent layer and the non-fluorescent layer) is unimportant. There may be situations where the non-fluorescent layer should be “on top” and situations where the non-fluorescent layer should be “on the bottom”. For example, when the LSC is molded in the shape of a skylight, it may be desirable for the non-fluorescent layer to be “on the bottom” so that it faces the interior of the house it is used in. This way, the homeowner can choose the viewing color s/he wishes to view. On the other hand, if the LSC is molded/used to replace the shingles of a home, it may be desirable for the non-fluorescent layer to be “on top” to blend into the roof. It should also be noted that the use of a non-fluorescent layer may reduce the light concentration directed to the light energy converter, but not as much as if the non-fluorescent dyes are added in the same layer as the fluorescent dyes.

The multi-layer nature of the sheet or panel in the LSC of the present disclosure allows the LSC viewing color to be customized, while at the same time allowing for sufficient concentration of light energy along the edge of the sheet. Thus, the potential viewing color of the LSC is no longer limited by the availability of suitably colored fluorescent dyes. This allows the LSC to be used in many more potential applications where the viewing color can affect the use of the LSC. The sheet or panel can be molded into any shape and has enhanced edge emission properties which make it highly suitable for use in a luminescent solar collector comprising the panel and a photocell. The LSC may be used as a building element for use on the roof, such as a skylight. The LSC can also be a component of a personal electronic device, such as a phone or laptop computer.

In a luminescent solar collector, the panel described above is used with a photocell. The photocell converts the light energy into electrical energy. Several different types of photocells may be used. Suitable bulk technology photocells include amorphous silicon cells, multicrystalline silicon cells, and monocrystalline silicon cells. Suitable thin film technology photocells include cadmium telluride cells, copper indium selenide cells, gallium arsenide or indium selenide cells, and copper indium gallium selenide cells. In specific embodiments, the photocell is a multicrystalline silicon photocell or a monocrystalline silicon photocell.

Generally, each type of photocell has a “sweet spot”, or a range of wavelengths (light energy) which it converts most efficiently into electric energy. The fluorescent dye in the fluorescent layer of the panel should be selected so that the light it emits matches, as much as possible, the sweet spot of the photocell. For example, the sweet spot of a multicrystalline silicon photocell or a monocrystalline silicon photocell is from about 700 nanometers to about 1100 nanometers.

Some specific fluorescent dyes which may be used include the following, which have the listed characteristics:

| | Absorption | Emission | % quantum |
|---|---|---|---|
| Dye | λₘₐₓ (nm) | λ (nm) | yield |
| Lumogen ® F Yellow 083 | 476 | 490 | >85 |
| Lumogen ® F Yellow 170 | 505 | 528 | >90 |
| Lumogen ® F Orange 240 | 524 | 539 | >90 |
| Lumogen ® F Pink 285 | 547 | 580 | >78 |
| Lumogen ® F Red 305 | 578 | 613 | >90 |
| Lumogen ® F Violet 570 | 378 | 413 | >85 |
| Lumogen ® F Blue 650 | 377 | 411 | >80 |
| Lumogen ® F Green 850 | 475 | 489 | >90 |

In addition to the components described hereinabove, the fluorescent and non-fluorescent layers may further include various other additives ordinarily incorporated with thermoplastic polymers of this type, with the proviso that the additives are selected so as not to adversely affect the desired properties of the polymer layer. Mixtures of additives may be used. Such additives may be mixed at a suitable time during the mixing of the components for forming the thermoplastic polymer.

The fluorescent and non-fluorescent layers may include fillers or reinforcing agents. Specifically, useful fillers as contemplated herein are visual effects fillers that possess compositional, shape and dimensional qualities useful to the reflection and/or refraction of light. Visual effect fillers include those having planar facets and can be multifaceted or in the form of flakes, shards, plates, leaves, wafers, and the like. The shape can be irregular or regular. A non-limiting example of a regular shape is a hexagonal plate. Visual effect fillers are two dimensional, plate-type fillers, wherein a particle of a plate type filler has a ratio of its largest dimension to smallest dimension of greater than or equal to 3:1, specifically greater than or equal to 5:1, and more specifically greater than or equal to 10:1. The largest dimension so defined can also be referred to as the diameter of the particle. Plate-type fillers have a distribution of particle diameters described by a minimum and a maximum particle diameter. The minimum particle diameter is described by the lower detection limit of the method used to determine particle diameter, and corresponds to it. A typical method of determining particle diameters is laser light scattering, which can for example have a lower detection limit for particle diameter of 0.6 nanometers. It should be noted that particles having a diameter less than the lower detection limit may be present but not observable by the method. The maximum particle diameter is typically less than the upper detection limit of the method. The maximum particle diameter herein may be less than or equal to 1,000 micrometers, specifically less than or equal to 500 micrometers. The distribution of particle diameters can be unimodal, bimodal, or multimodal. The diameter can be described more generally using the mean of the distribution of the particle diameters, also referred to as the mean diameter. Useful particles may have a mean diameter of 1 to 100 micrometers, specifically 5 to 75 micrometers, and more specifically 10 to 60 micrometers. The particles may also be in the form of nanoparticles, i.e., particles with a median particle size (D₅₀) smaller than 100 nm as determined using light scattering methods. Specific reflective fillers have an optically dense surface exterior finish useful for reflecting incident light. Metallic and non-metallic fillers such as those based on aluminum, silver, copper, bronze, steel, brass, gold, tin, silicon, alloys of these, combinations comprising at least one of the foregoing metals, and the like, are specifically useful. Also specifically useful are inorganic fillers prepared from a composition presenting a surface that is useful for reflecting and/or refracting incident light. In contrast to a reflective filler, a refractive filler having refractive properties can be at least partially transparent, i.e., can allow transmission of a percentage of incident light, and can provide optical properties based on reflection, refraction, or a combination of reflection and refraction of incident light, Inorganic fillers having light reflecting and/or refracting properties useful herein may include micas, alumina, silica, silicon carbide, glass, combinations comprising at least one of the foregoing inorganic fillers, and the like.

The fillers may be coated with a layer of metallic material to facilitate conductivity where desired, or surface treated with silanes to improve adhesion, dispersion, and/or optical properties with the polymeric matrix resin. Where used, fillers can be present in amounts of 0 to 90 percent by weight, based on the total weight of the layer.

The fluorescent and non-fluorescent layers can include an antioxidant. Useful antioxidant additives include, for example, organophosphites such as tris(nonyl phenyl)phosphite, tris(2,4-di-t-butylphenyl)phosphite, bis(2,4-di-t-butylphenyl)pentaerythritol diphosphite, distearyl pentaerythritol diphosphite or the like; alkylated monophenols or polyphenols; alkylated reaction products of polyphenols with dienes, such as tetrakis[methylene(3,5-di-tert-butyl-4-hydroxyhydrocinnamate)]methane, or the like; butylated reaction products of para-cresol or dicyclopentadiene; alkylated hydroquinones; hydroxylated thiodiphenyl ethers; alkylidene-bisphenols; benzyl compounds; esters of beta-(3,5-di-tert-butyl-4-hydroxyphenyl)-propionic acid with monohydric or polyhydric alcohols; esters of beta-(5-tert-butyl-4-hydroxy-3-methylphenyl)-propionic acid with monohydric or polyhydric alcohols; esters of thioalkyl or thioaryl compounds such as distearylthiopropionate, dilaurylthiopropionate, ditridecylthiodipropionate, octadecyl-3-(3,5-di-tert-butyl-4-hydroxyphenyl)propionate, pentaerythrityl-tetrakis[3-(3,5-di-tert-butyl-4-hydroxyphenyl)propionate or the like; amides of beta-(3,5-di-tert-butyl-4-hydroxyphenyl)-propionic acid or the like, or combinations comprising at least one of the foregoing antioxidants. Antioxidants can be used in amounts of 0.0001 to 1 percent by weight, based on the total weight of the layer.

Useful heat stabilizer additives include, for example, organophosphites such as triphenyl phosphite, tris-(2,6-dimethylphenyl)phosphite, tris-(mixed mono- and di-nonylphenyl)phosphite or the like; phosphonates such as dimethylbenzene phosphonate or the like, phosphates such as trimethyl phosphate, or the like, or combinations comprising at least one of the foregoing heat stabilizers. Heat stabilizers can be used in amounts of 0.0001 to 1 percent by weight, based on the total weight of the layer.

Light stabilizers and/or ultraviolet light (UV) absorbing additives may also be used. Useful light stabilizer additives include, for example, benzotriazoles such as 2-(2-hydroxy-5-methylphenyl)benzotriazole, 2-(2-hydroxy-5-tert-octylphenyl)-benzotriazole and 2-hydroxy-4-n-octoxy benzophenone, or the like, or combinations comprising at least one of the foregoing light stabilizers. Light stabilizers can be used in amounts of 0.0001 to 1 percent by weight, based on the total weight of the layer.

Useful UV absorbing additives include for example, hydroxybenzophenones; hydroxybenzotriazoles; hydroxybenzotriazines; cyanoacrylates; oxanilides; benzoxazinones; 2-(2H-benzotriazol-2-yl)-4-(1,1,3,3-tetramethylbutyl)-phenol (CYASORB® 5411); 2-hydroxy-4-n-octyloxybenzophenone (CYASORB® 531); 2-[4,6-bis(2,4-dimethylphenyl)-1,3,5-triazin-2-yl]-5-(octyloxy)-phenol (CYASORB® 1164); 2,2′-(1,4-phenylene)bis(4H-3,1-benzoxazin-4-one) (CYASORB® UV-3638); 1,3-bis[(2-cyano-3,3-diphenylacryloyl)oxy]-2,2-bis[[(2-cyano-3,3-diphenylacryloyl)oxy]methyl]propane (UVINUL® 3030); 2,2′-(1,4-phenylene)bis(4H-3,1-benzoxazin-4-one); 1,3-bis[(2-cyano-3,3-diphenylacryloyl)oxy]-2,2-bis[[(2-cyano-3,3-diphenylacryloyl)oxy]methyl]propane; nano-size inorganic materials such as titanium oxide, cerium oxide, and zinc oxide, all with particle size less than 100 nanometers; or the like, or combinations comprising at least one of the foregoing UV absorbers. UV absorbers can be used in amounts of 0.0001 to 1 percent by weight, based on the total weight of the layer.

Plasticizers, lubricants, and/or mold release agents additives may also be used. There is considerable overlap among these types of materials, which include, for example, phthalic acid esters such as dioctyl-4,5-epoxy-hexahydrophthalate; tris-(octoxycarbonylethyl)isocyanurate; tristearin; di- or polyfunctional aromatic phosphates such as resorcinol tetraphenyl diphosphate (RDP), the bis(diphenyl)phosphate of hydroquinone and the bis(diphenyl)phosphate of bisphenol-A; poly-alpha-olefins; epoxidized soybean oil; silicones, including silicone oils; esters, for example, fatty acid esters such as alkyl stearyl esters, e.g., methyl stearate; stearyl stearate, pentaerythritol tetrastearate, and the like; mixtures of methyl stearate and hydrophilic and hydrophobic nonionic surfactants comprising polyethylene glycol polymers, polypropylene glycol polymers, and copolymers thereof, e.g., methyl stearate and polyethylene-polypropylene glycol copolymers in a suitable solvent; waxes such as beeswax, montan wax, paraffin wax or the like. Such materials can be used in amounts of 0.001 to 1 percent by weight, based on the total weight of the layer.

The fluorescent and non-fluorescent layers can include antistatic agents. The term “antistatic agent” refers to monomeric, oligomeric, or polymeric materials that can be processed into polymer resins and/or sprayed onto materials or articles to improve conductive properties and overall physical performance. Examples of monomeric antistatic agents include glycerol monostearate, glycerol distearate, glycerol tristearate, ethoxylated amines, primary, secondary and tertiary amines, ethoxylated alcohols, alkyl sulfates, alkylarylsulfates, alkylphosphates, alkylaminesulfates, alkyl sulfonate salts such as sodium stearyl sulfonate, sodium dodecylbenzenesulfonate or the like, quaternary ammonium salts, quaternary ammonium resins, imidazoline derivatives, sorbitan esters, ethanolamides, betaines, or the like, or combinations comprising at least one of the foregoing monomeric antistatic agents.

Exemplary polymeric antistatic agents include certain polyesteramides polyether-polyamide (polyetheramide) block copolymers, polyetheresteramide block copolymers, polyetheresters, or polyurethanes, each containing polyalkylene glycol moieties polyalkylene oxide units such as polyethylene glycol, polypropylene glycol, polytetramethylene glycol, and the like. Such polymeric antistatic agents are commercially available, for example Pelestat®6321 (Sanyo) or Pebax®MH1657 (Atofina), Irgastat®P18 and P22 (Ciba-Geigy). Other polymeric materials that may be used as antistatic agents are inherently conducting polymers such as polyaniline (commercially available as PANIPOL®EB from Panipol), polypyrrole, and polythiophenes such as for example poly(3,4-ethylenedioxythiophene) (commercially available from H. C. Stark), which retain some of their intrinsic conductivity after melt processing at elevated temperatures. Another exemplary antistatic agent is tetrabutyl phosphonium salt of perfluorobutylsulfonate. In one embodiment, carbon fibers, carbon nanofibers, carbon nanotubes, carbon black, or any combination of the foregoing may be used in a polymeric resin containing chemical antistatic agents to render the polymer layer electrostatically dissipative. Antistatic agents can be used in amounts of 0.0001 to 5 percent by weight, based on the total weight of the layer.

The fluorescent and non-fluorescent layers can include flame retardants. Flame retardant that may be added may be organic compounds that include phosphorus, bromine, and/or chlorine. Non-brominated and non-chlorinated phosphorus-containing flame retardants may be preferred in certain applications for regulatory reasons, for example organic phosphates and organic compounds containing phosphorus-nitrogen bonds. Inorganic flame retardants may also be used.

One type of exemplary organic phosphate is an aromatic phosphate of the formula (GO)₃P═O, wherein each G is independently an alkyl, cycloalkyl, aryl, alkylaryl, or arylalkyl group, provided that at least one G is an aromatic group. Two of the G groups may be joined together to provide a cyclic group, for example, diphenyl pentaerythritol diphosphate. Other useful aromatic phosphates may be, for example, phenyl bis(dodecyl)phosphate, phenyl bis(neopentyl)phosphate, phenyl bis(3,5,5′-trimethylhexyl)phosphate, ethyl diphenyl phosphate, 2-ethylhexyl di(p-tolyl)phosphate, bis(2-ethylhexyl)p-tolyl phosphate, tritolyl phosphate, bis(2-ethylhexyl)phenyl phosphate, tri(nonylphenyl)phosphate, bis(dodecyl)p-tolyl phosphate, dibutyl phenyl phosphate, 2-chloroethyl diphenyl phosphate, p-tolyl bis(2,5,5′-trimethylhexyl)phosphate, 2-ethylhexyl diphenyl phosphate, or the like. A specific aromatic phosphate is one in which each G is aromatic, for example, triphenyl phosphate, tricresyl phosphate, isopropylated triphenyl phosphate, and the like.

Di- or polyfunctional aromatic phosphorus-containing compounds are also useful, for example, compounds of the formulas below:

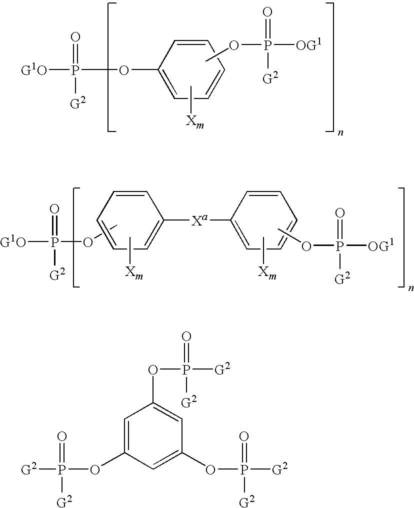

wherein each G¹ is independently a hydrocarbon having 1 to 30 carbon atoms; each G² is independently a hydrocarbon or hydrocarbonoxy having 1 to 30 carbon atoms; each X^{a} is independently a hydrocarbon having 1 to 30 carbon atoms; each X is independently a bromine or chlorine; m is 0 to 4, and n is 1 to 30. Examples of useful di- or polyfunctional aromatic phosphorus-containing compounds include resorcinol tetraphenyl diphosphate (RDP), the bis(diphenyl)phosphate of hydroquinone and the bis(diphenyl)phosphate of bisphenol-A, respectively, their oligomeric and polymeric counterparts, and the like.

Exemplary flame retardant compounds containing phosphorus-nitrogen bonds include phosphonitrilic chloride, phosphorus ester amides, phosphoric acid amides, phosphonic acid amides, phosphinic acid amides, tris(aziridinyl)phosphine oxide. When present, phosphorus-containing flame retardants can be present in amounts of 0.1 to 10 percent by weight, based on the total weight of the layer.

Halogenated materials may also be used as flame retardants, for example halogenated compounds and resins of formula (31):

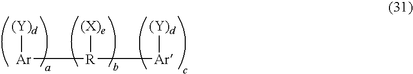

wherein R is an alkylene, alkylidene or cycloaliphatic linkage, e.g., methylene, ethylene, propylene, isopropylene, isopropylidene, butylene, isobutylene, amylene, cyclohexylene, cyclopentylidene, or the like; or an oxygen ether, carbonyl, amine, or a sulfur containing linkage, e.g., sulfide, sulfoxide, sulfone, or the like. R can also consist of two or more alkylene or alkylidene linkages connected by such groups as aromatic, amino, ether, carbonyl, sulfide, sulfoxide, sulfone, or the like.

Ar and Ar′ in formula (31) are each independently mono- or polycarbocyclic aromatic groups such as phenylene, biphenylene, terphenylene, naphthylene, or the like. Also in formula (31), Y is an organic, inorganic, or organometallic radical, for example: halogen, e.g., chlorine, bromine, iodine, fluorine; ether groups of the general formula OE, wherein E is a monovalent hydrocarbon radical similar to X; monovalent hydrocarbon groups of the type represented by R; or other substituents, e.g., nitro, cyano, and the like, said substituents being essentially inert provided that there is at least one and preferably two halogen atoms per aryl nucleus.

When present, each X is independently a monovalent hydrocarbon group, for example an alkyl group such as methyl, ethyl, propyl, isopropyl, butyl, decyl, or the like; an aryl groups such as phenyl, naphthyl, biphenyl, xylyl, tolyl, or the like; and arylalkyl group such as benzyl, ethylphenyl, or the like; a cycloaliphatic group such as cyclopentyl, cyclohexyl, or the like. The monovalent hydrocarbon group may itself contain inert substituents.

Each d is independently 1 to a maximum equivalent to the number of replaceable hydrogens substituted on the aromatic rings comprising Ar or Ar′. Each e is independently 0 to a maximum equivalent to the number of replaceable hydrogens on R. Each a, b, and c is independently a whole number, including 0. When b is not 0, neither a nor c may be 0. Otherwise either a or c, but not both, may be 0. Where b is 0, the aromatic groups are joined by a direct carbon-carbon bond.

The hydroxyl and Y substituents on the aromatic groups, Ar and Ar′, can be varied in the ortho, meta or para positions on the aromatic rings and the groups can be in any possible geometric relationship with respect to one another.

Included within the scope of the above formula are bisphenols of which the following are representative: 2,2-bis-(3,5-dichlorophenyl)-propane; bis-(2-chlorophenyl)-methane; bis(2,6-dibromophenyl)-methane; 1,1-bis-(4-iodophenyl)-ethane; 1,2-bis-(2,6-dichlorophenyl)-ethane; 1,1-bis-(2-chloro-4-iodophenyl)ethane; 1,1-bis-(2-chloro-4-methylphenyl)-ethane; 1,1-bis-(3,5-dichlorophenyl)-ethane; 2,2-bis-(3-phenyl-4-bromophenyl)-ethane; 2,6-bis-(4,6-dichloronaphthyl)-propane; 2,2-bis-(2,6-dichlorophenyl)-pentane; 2,2-bis-(3,5-dibromophenyl)-hexane; bis-(4-chlorophenyl)-phenyl-methane; bis-(3,5-dichlorophenyl)-cyclohexylmethane; bis-(3-nitro-4-bromophenyl)-methane; bis-(4-hydroxy-2,6-dichloro-3-methoxyphenyl)-methane; and 2,2-bis-(3,5-dichloro-4-hydroxyphenyl)-propane 2,2 bis-(3-bromo-4-hydroxyphenyl)-propane. Also included within the above structural formula are: 1,3-dichlorobenzene, 1,4-dibromobenzene, 1,3-dichloro-4-hydroxybenzene, and biphenyls such as 2,2′-dichlorobiphenyl, polybrominated 1,4-diphenoxybenzene, 2,4′-dibromobiphenyl, and 2,4′-dichlorobiphenyl as well as decabromo diphenyl oxide, and the like.

Also useful are oligomeric and polymeric halogenated aromatic compounds, such as a copolycarbonate of bisphenol-A and tetrabromobisphenol-A and a carbonate precursor, e.g., phosgene. Metal synergists, e.g., antimony oxide, may also be used with the flame retardant. When present, halogen containing flame retardants can be present in amounts of 0.1 to 10 percent by weight, based on the total weight of the layer.

The fluorescent and non-fluorescent layers can include an anti-drip agent. Anti-drip agents may be, for example, a fibril forming or non-fibril forming fluoropolymer such as polytetrafluoroethylene (PTFE). The anti-drip agent may be encapsulated by a rigid copolymer as described above, for example styrene-acrylonitrile copolymer (SAN). PTFE encapsulated in SAN is known as TSAN. Encapsulated fluoropolymers may be made by polymerizing the encapsulating polymer in the presence of the fluoropolymer, for example an aqueous dispersion. TSAN may provide significant advantages over PTFE, in that TSAN may be more readily dispersed in the polymer layer. A useful TSAN may comprise, for example, 50 wt % PTFE and 50 wt % SAN, based on the total weight of the encapsulated fluoropolymer. The SAN may comprise, for example, 75 wt % styrene and 25 wt % acrylonitrile based on the total weight of the copolymer. Alternatively, the fluoropolymer may be pre-blended in some manner with a second polymer, such as for, example, an aromatic polycarbonate resin or SAN to form an agglomerated material for use as an anti-drip agent. Either method may be used to produce an encapsulated fluoropolymer. Antidrip agents can be used in amounts of 0.1 to 5 percent by weight, based on the total weight of the layer.

The fluorescent and non-fluorescent layers may further comprise an ionizing radiation stabilizing additive. Exemplary ionizing radiation stabilizing additives include certain aliphatic alcohols, aromatic alcohols, aliphatic diols, aliphatic ethers, esters, diketones, alkenes, thiols, thioethers and cyclic thioethers, sulfones, dihydroaromatics, diethers, nitrogen compounds, or a combination comprising at least one of the foregoing. Alcohol-based stabilizing additives may be selected from mono, di-, or polysubstituted alcohols, and can be straight, branched, cyclic and/or aromatic. Useful aliphatic alcohols may include alkenols with sites of unsaturation, examples of which include 4-methyl-4-penten-2-ol, 3-methyl-pentene-3-ol, 2-methyl-4-penten-2-ol, 2,4-dimethyl-4-penten-2-ol, 2-phenyl-4-penten-2-ol, and 9-decen-1-ol; tertiary alcohols including 3-hydroxy-3-methyl-2-butanone, 2-phenyl-2-butanol, and the like; hydroxy-substituted tertiary cycloaliphatics such as 1-hydroxy-1-methyl-cyclohexane; and hydroxymethyl aromatics having an aromatic ring with carbinol substituents such as a methylol group (—CH₂OH) or a more complex hydrocarbon group such as (—CRHOH) or (—CR₂OH), wherein R is straight chain C₁-C₂₀ alkyl or branched C₁-C₂₀ alkyl. Exemplary hydroxy carbinol aromatics include benzhydrol, 2-phenyl-2-butanol, 1,3-benzenedimethanol, benzyl alcohol, 4-benzyloxy-benzyl alcohol, and 4-benzyl-benzyl alcohol.

Useful classes of ionizing radiation stabilizing additives are di- and polyfunctional aliphatic alcohols, also referred to as aliphatic diols and aliphatic polyols. Specifically useful are aliphatic diols of formula (32):

HO—(C(A′)(A″))d-S—(C(B′)(B″))e-OH (32)

wherein A′, A″, B′, and B″ are each independently H or C₁-C₆ alkyl; S is C₁-C₂₀ alkyl, C₂-C₂₀ alkyleneoxy, C₃-C₆ cycloalkyl, or C₃-C₆ substituted cycloalkyl; and d and e are each 0 or 1, with the proviso that, when d and e are each 0, S is selected such that both —OH groups are not connected directly to a single common carbon atom.

In formula (32), A′, A″, B′, and B″ can each be independently selected from H, methyl, ethyl, n-propyl, isopropyl, n-butyl, sec-butyl, t-butyl, n-pentyl, 2-pentyl, 3-pentyl, isopentyl, neopentyl, n-hexyl, 2-hexyl, 3-hexyl, 2-methyl pentyl, 3-methylpentyl, 2,2 dimethylbutyl, 2,3-dimethylbutyl, and the like, and a combination comprising at least one of the foregoing alkyl groups.

Spacer group S can be selected from methanediyl, ethanediyl, 1,1-ethanediyl, 1,1-propanediyl, 1,2-propanediyl, 1,3-propanediyl, 2,2-propanediyl, 1,1-butanediyl, 1,2-butanediyl, 1,3-butanediyl, 1,4-butanediyl, 2,2-butanediyl, 2,3-butanediyl, 1,1-pentanediyl, 1,2-pentanediyl, 1,3-pentanediyl, 1,4-pentanediyl, 1,5-pentanediyl, 2,2-pentanediyl, 2,3-pentanediyl, 2,4-pentanediyl, 3,3-pentanediyl, 2-methyl-1,1-butanediyl, 3-methyl-1,1-butanediyl, 2-methyl-1,2-butanediyl, 2-methyl-1,3-butanediyl, 2-methyl-1,4-butanediyl, 2-methyl-2,2-butanediyl, 2-methyl-2,3-butanediyl, 2,2-dimethyl-1,1-propanediyl, 2,2-dimethyl-1,2-propanediyl, 2,2-dimethyl-1,3-propanediyl, 3,3-dimethyl-1,1-propanediyl, 3,3-dimethyl-1,2-propanediyl, 3,3-dimethyl-2,2-propanediyl, 1,1-dimethyl-2,3-propanediyl, 3,3-dimethyl-2,2-propanediyl, 1,1-hexanediyl, 1,2-hexanediyl, 1,3-hexanediyl, 1,4-hexanediyl, 1,5-hexanediyl, 1,6-hexanediyl, 2,2-hexanediyl, 2,3-hexanediyl, 2,4-hexanediyl, 2,5-hexanediyl, 3,3-hexanediyl, 2-methyl-1,1-pentanediyl, 3-methyl-1,1-pentanediyl, 2-methyl-1,2-pentanediyl, 2-methyl-1,3-pentanediyl, 2-methyl-1,4-pentanediyl, 2-methyl-2,2-pentanediyl, 2-methyl-2,3-pentanediyl, 2-methyl-2,4-pentanediyl, 2,2-dimethyl-1,1-butanediyl, 2,2-dimethyl-1,2-butanediyl, 2,2-dimethyl-1,3-butanediyl, 3,3-dimethyl-1,1-butanediyl, 3,3-dimethyl-1,2-butanediyl, 3,3-dimethyl-2,2-butanediyl, 1,1-dimethyl-2,3-butanediyl, 3,3-dimethyl-2,2-butanediyl, and the like; isomers of octanediyl, decanediyl, undecanediyl, dodecanediyl, hexadecanediyl, octadecanediyl, icosananediyl, and docosananediyl; and substituted and unsubstituted cyclopropanediyl, cyclobutanediyl, cyclopentanediyl, cyclohexanediyl, wherein substituents may be the points of radical attachment, such as in 1,4-dimethylenecyclohexane, or may include branched and straight chain alkyl, cycloalkyl, and the like. Additionally, the spacer group S may be selected from one or more diradicals comprising polyalkyleneoxy units, such as ethyleneoxy, 1,2-propyleneoxy, 1,3-propyleneoxy, 1,2-butyleneoxy, 1,4-butyleneoxy, 1,6-hexyleneoxy, and the like; and a combination comprising at least one of these.

Specific examples of useful aliphatic diols include ethylene glycol, propylene glycol, 1,3-propanediol, 1,2-butanediol, 1,4-butanediol, meso-2,3-butanediol, 1,2-pentanediol, 2,3-pentanediol, 1,4-pentanediol, 1,4-hexandiol, and the like; alicyclic alcohols such as 1,3-cyclobutanediol, 2,2,4,4-tetramethylcyclobutanediol, 1,2-cyclopentanediol, 1,2-cyclohexanediol, 1,3-cyclohexanediol, 1,4-cyclohexanediol, 1,4-dimethylolcyclohexane, and the like; branched acyclic diols such as 2,3-dimethyl-2,3-butanediol (pinacol), and 2-methyl-2,4-pentanediol (hexylene glycol); and polyalkyleneoxy-containing alcohols such as polyethylene glycol, polypropylene glycol, block or random poly(ethyleneglycol-co-propyleneglycols), and diols of copolymers containing polyalkyleneoxy-groups. Useful polyols may include polyaryleneoxy compounds such as polyhydroxystyrene; alkyl polyols such as polyvinylalcohol, polysaccharides, and esterified polysaccharides. A combination comprising at least one of the foregoing may also be useful. Specifically useful diols include 2-methyl-2,4-pentanediol (hexylene glycol), polyethylene glycol, and polypropylene glycol.

Useful aliphatic ethers may include alkoxy-substituted cyclic or acyclic alkanes such as, for example, 1,2-dialkoxyethanes, 1,2-dialkoxypropanes, 1,3-dialkoxypropanes, alkoxycyclopentanes, alkoxycyclohexanes, and the like. Ester compounds (—COOR) may be useful as stabilizers wherein R may be a substituted or unsubstituted, aromatic or aliphatic, hydrocarbon and the parent carboxy compound may likewise be substituted or unsubstituted, aromatic or aliphatic, and/or mono- or polyfunctional. When present, substituents may include, for example, C₁-C₈ alkyl, C₁-C₈ alkyl ether, C₆-C₂₀ aryl, and the like. Esters which have proven useful include tetrakis(methylene [3,5-di-t-butyl-4-hydroxy-hydrocinnamate])methane, 2,2′-oxamido bis(ethyl-3-(3,5-di-t-butyl-4-hydroxyphenyl)propionate, and trifunctional hindered phenolic ester compounds such as GOOD-RITE® 3125, available from B.F. Goodrich in Cleveland Ohio.

Diketone compounds may also be used, specifically those having two carbonyl functional groups and separated by a single intervening carbon atoms such as, for example 2,4-pentadione.

Sulfur-containing compounds, useful for use as stabilizing additives, can include thiols, thioethers and cyclic thioethers. Thiols include, for example, 2-mercaptobenzothiazole; thioethers include dilaurylthiopropionate; and cyclic thioethers include 1,4-dithiane, 1,4,8,11-tetrathiocyclotetradecane. Cyclic thioethers containing more than one thioether group are useful, specifically those having a single intervening carbon between two thioether groups such as in, for example, 1,3-dithiane. The cyclic ring may contain oxygen or nitrogen members.

Aryl or alkyl sulfone stabilizing additives of general structure R—S(O)₂—R′ may also be used, where R and R′ comprise C₁-C₂₀ alkyl, C₆-C₂₀ aryl, C₁-C₂₀ alkoxy, C₆-C₂₀ aryloxy, substituted derivatives thereof, and the like, and wherein at least one of R or R′ is a substituted or unsubstituted benzyl. When present, substituents may include, for example, C₁-C₈ alkyl, C₁-C₈ alkyl ether, C₆-C₂₀ aryl, and the like. An example of a specifically useful sulfone is benzylsulfone.

Hydroaromatic compounds may also be useful as stabilizing additives, including partially hydrogenated aromatics, and aromatics in combination with an unsaturated ring. Specific aromatics include benzene and/or naphthalene based systems. Examples of hydroaromatic compounds include indane, 5,6,7,8-tetrahydro-1-naphthol, 5,6,7,8-tetrahydro-2-naphthol, 9,10-dihydroanthracene, 9,10-dihydrophenanthrene, 1-phenyl-1-cyclohexane, 1,2,3,4-tetrahydro-1-naphthol, and the like, or a combination comprising at least one of the foregoing.

Diethers, including hydrogenated and nonhydrogenated, and substituted and unsubstituted pyrans, may also be used as stabilizing additives. When present, substituents may include C₁-C₈ alkyl, C₁-C₈ alkyl ether, or C₆-C₂₀ aryl. The pyrans may have substituents including C₁-C₂₀ alkyl, C₆-C₂₀ aryl, C₁-C₂₀ alkoxy, or C₆-C₂₀ aryloxy, and which may be positioned on any carbon of the pyran ring. Specifically useful substituent groups include C₁-C₂₀ alkoxy or C₆-C₂₀ aryloxy, located on the ring at the six position. Hydrogenated pyrans are specifically useful. Examples of diethers include dihydropyranyl ethers and tetrahydropyranyl ethers.

Nitrogen compounds which may function as stabilizers include high molecular weight oxamide phenolics, for example, 2,2-oxamido bis-[ethyl 3-(3,5-di-tert-butyl-4-hydroxyphenyl)propionate], high molecular weight oxalic anilides and their derivatives, and amine compounds such as thiourea.

Ionizing radiation stabilizing additives are typically used in amounts of 0.001 to 1 wt %, specifically 0.005 to 0.75 wt %, more specifically 0.01 to 0.5 wt %, and still more specifically 0.05 to 0.25 wt %, based on the total weight of the layer. In an embodiment, a specifically useful ionizing radiation stabilizing additive is an aliphatic diol.

Consequently, examples of non-limiting additives that may be included in the first and second polymer layers include optical effects filler, antioxidant, heat stabilizer, light stabilizer, ultraviolet light absorber, plasticizer, mold release agent, lubricant, antistatic agent, flame retardant, anti-drip agent, gamma stabilizer, or a combination comprising at least one of the foregoing additives.

The polymer layers may be manufactured by methods generally available in the art. For example, in one embodiment, in one manner of proceeding, powdered polycarbonate and dye (fluorescent or non-fluorescent, depending on which layer is being made) are first blended in a HENSCHEL-Mixer® high speed mixer. Other low shear processes including but not limited to hand mixing may also accomplish this blending. The blend is then fed into the throat of an extruder via a hopper. Alternatively, one or more of the components may be incorporated into the composition by feeding directly into the extruder at the throat and/or downstream through a sidestuffer. Additives may also be compounded into a masterbatch with a desired polymeric resin and fed into the extruder. The extruder is generally operated at a temperature higher than that necessary to cause the composition to flow. The extrudate is immediately quenched in a water batch and pelletized. The pellets, so prepared, when cutting the extrudate may be one-fourth inch long or less as desired. Such pellets may be used for subsequent molding, shaping, or forming. The polymer layers may be molded from the thermoplastic composition by a variety of means such as injection molding, extrusion, rotational molding, blow molding and thermoforming. In a specific embodiment, molding is done by injection molding.

The following examples are provided to illustrate the LSC having customizable viewing color of the present disclosure. The examples are merely illustrative and are not intended to limit devices made in accordance with the disclosure to the materials, conditions, or process parameters set forth therein. All parts are percentages by volume unless otherwise indicated.

### EXAMPLES

Nine samples were produced. Each sample was a chip of dimensions 60 mm×60 mm×3.2 mm and having the composition shown in Table 1. CE refers to Comparative Examples and Ex refers to Examples. The Reference, CE1, and CE2 samples were single-layer chips. Ex1-Ex6 were dual-layer chips. The chips Ex1-Ex6 also had a total thickness of 6.4 mm; each exterior and interior layer was 3.2 mm respectively. The chips had smooth top and bottom surfaces. For reference, Lumogen® F Red 305 is a fluorescent dye from BASF, whereas Pigment Blue 15:4, Pigment Blue 60, Solvent Green 3, and Solvent Yellow 163 are non-fluorescent dyes or pigments. PETS (pentaerythritol tetrastearate) is a mold release agent available from Henkel. The phosphate stabilizer used was IRGAFOS® 168 tris(2,4-ditert-butylphenyl)phosphate from CIBA Specialty Chemicals. In the dual-layer chips, the two layers were glued together using GE Silicones RTV 6166 two-part silicone according to the instructions provided with the silicone and cured overnight.

The viewing color was measured with a MacBeth ColorEye 7000 spectrophotometer. A solar simulator (PET SS200B simulator with a class B xenon lamp) illuminated each chip under AM1 illumination (air mass 1.5 spectral curve) and a power of 1000 W/m² for an area of 200 mm×200 mm. A calibrated Ocean Optics HD200 spectrophotometer (range 380 nm to 1100 nm, resolution of 0.5 nm) with an optical fibre probe and attached collimating lens was used to determine the intensity of the edge emission per area (W/m²). The spectrophotometer was calibrated over 300 nm to 1050 nm using a bulb with a 3100K color temperature. The results are also shown in Table 1. The resulting color as observed by a human observer is reported as “viewing color”.

TABLE 1
Compositions and Results

| | Reference | CE1 | Ex1 | | Ex2 | |
|---|---|---|---|---|---|---|
| | Single | Single | Exterior | Interior | Exterior | Interior |
| | layer | layer | layer | layer | layer | layer |
| Polycarbonate | 99.648 | 99.6457 | 99.648 | 99.6477 | 99.6477 | 99.648 |
| Lumogen F Red 305 | 0.002 | 0.002 | 0.002 | | | 0.002 |
| PETS | 0.3 | 0.3 | 0.3 | 0.3 | 0.3 | 0.3 |
| Phosphite | 0.05 | 0.05 | 0.05 | 0.05 | 0.05 | 0.05 |
| Heliogen Blue K7100 | | 0.0003 | | 0.0003 | 0.0003 | |
| Pigment Blue 60 | | 0.002 | | 0.002 | 0.002 | |
| MBX 5 | | | | | | |
| Macrolex Green 5B | | | | | | |
| Oracet Yellow GHS | | | | | | |

Results

| | | | | | | |
|---|---|---|---|---|---|---|
| Edge emission | 93 | 6 | 67 | 5 | 4 | 66 |
| (W/sq. m.) | | | | | | |

| | | | | |
|---|---|---|---|---|
| L* | 81.8 | 78.9 | 75 | 75.2 |
| a* | 15.9 | −3.1 | −0.4 | 0.5 |
| b* | −7.2 | −14.3 | −15.8 | −15.4 |
| Viewing Color | Red | Blue | Blue | Blue |

| | Ex3 | | Ex4 | |
|---|---|---|---|---|
| | Exterior | Interior | Exterior | Interior |
| | layer | layer | layer | layer |
| Polycarbonate | 99.648 | 99.1477 | 99.1477 | 99.648 |
| Lumogen F Red 305 | 0.002 | | | 0.002 |
| PETS | 0.3 | 0.3 | 0.3 | 0.3 |
| Phosphite | 0.05 | 0.05 | 0.05 | 0.05 |
| Heliogen Blue K7100 | | 0.0003 | 0.0003 | |
| Pigment Blue 60 | | 0.002 | 0.002 | |
| MBX 5 | | 0.5 | 0.5 | |
| Macrolex Green 5B | | | | |
| Oracet Yellow GHS | | | | |

Results

| | | | | |
|---|---|---|---|---|
| Edge emission | 74 | 25 | 26 | 71 |
| (W/sq. m.) | | | | |

| | | |
|---|---|---|
| L* | 71.9 | 73.4 |
| a* | 1 | 1.1 |
| b* | −13.3 | −13 |
| Viewing Color | Grey/Blue | Grey/Blue |

| | CE2 | Ex5 | | Ex6 | |
|---|---|---|---|---|---|
| | Single | Exterior | Interior | Exterior | Interior |
| | layer | layer | layer | layer | layer |
| Polycarbonate | 99.643 | 99.648 | 99.645 | 99.645 | 99.648 |
| Lumogen F Red 305 | 0.002 | 0.002 | | | 0.002 |
| PETS | 0.3 | 0.3 | 0.3 | 0.3 | 0.3 |
| Phosphite | 0.05 | 0.05 | 0.05 | 0.05 | 0.05 |
| Heliogen Blue K7100 | | | | | |
| Pigment Blue 60 | | | | | |
| MBX 5 | | | | | |
| Macrolex Green 5B | 0.002 | | 0.002 | 0.002 | |
| Oracet Yellow GHS | 0.003 | | 0.003 | 0.003 | |

Results

| | | | | | |
|---|---|---|---|---|---|
| Edge emission | 12 | 61 | 7 | 5 | 45 |
| (W/sq. m.) | | | | | |

| | | | |
|---|---|---|---|
| L* | 73 | 71.3 | 71.3 |
| a* | −5 | −2.8 | −2.5 |
| b* | 6.2 | 5.8 | 5.8 |
| Viewing Color | Grey/Green | Grey | Grey |

The Heliogen® Blue K7100 was from BASF. The Macrolex® Green 5B was from Lanxess. The Oracet® Yello GHS was from CIBA.

L* is the lightness, a* is the red/green axis, and b* is the yellow/blue axis according to CIELAB standards. The L*, a*, and b* values in Table 1 refer to the viewing color as measured by the MacBeth ColorEye. By comparing the L*, a*, and b* values between the Reference, Ex1, and Ex2, it was shown that the viewing color could be customized. In comparing CE1 with Ex1 and Ex2, as well as comparing CE2 with Ex5 and Ex6, it was shown that the two-layer system retained a higher level of edge emission than combining the fluorescent and non-fluorescent dye or pigments in the same layer (total emission of 72 and 70 W/m² versus 6 W/m² for Ex1, Ex2, and CE1 respectively; total emission of 68 and 50 W/m² versus 12 W/m² for Ex5, Ex6, and CE2 respectively). It was also shown that the order of the fluorescent and non-fluorescent layers did not significantly affect the level of edge emission. Ex3 and Ex4 show that a diffuser can be added to the non-fluorescent layer without adversely affecting the level of edge emission. In fact, use of a diffuser increased the level of edge emission by over 30%. While the levels of edge emission for Ex1, Ex2, Ex5, and Ex6 were lower than the Reference, the ability to use the LSC in more applications compensates for this reduction in level of edge emission. Furthermore, the levels displayed in the Examples are still sufficient for commercial use. Table 1 also shows that the viewing color, as seen by a human observer, is highly customizable and can vary from a red color to a more aesthetically pleasing grey, green, or blue color.

The luminescent solar collector of the present disclosure has been described with reference to exemplary embodiments. Obviously, modifications and alterations will occur to others upon reading and understanding the preceding detailed description. It is intended that the exemplary embodiments be construed as including all such modifications and alterations insofar as they come within the scope of the appended claims or the equivalents thereof.

1. A luminescent solar collector having a customizable viewing color, comprising a sheet and a light energy converter;
the sheet comprising a first layer and a second layer operatively connected to the first layer along an adjoining surface;
the light energy converter operatively connected to the first layer;
the first layer comprising a first polymer and a fluorescent dye or quantum dot dispersed therein, wherein the fluorescent dye or quantum dot absorbs light and radiates the absorbed light at a longer wavelength, and wherein the first layer is configured in a manner to transmit the radiated light to the light energy converter; and
the second layer comprising a second polymer and a non-fluorescent dye or pigment dispersed therein, wherein the non-fluorescent dye or pigment contributes to the customizable viewing color of the luminescent solar collector.

2. The luminescent solar collector of claim 1, wherein the first polymer and second polymer each independently comprise a polycarbonate.

3. The luminescent solar collector of claim 1, wherein the first polymer and second polymer each independently comprise a polyester-polycarbonate.

4. The luminescent solar collector of claim 1, wherein the fluorescent dye is selected from the group consisting of perylene and terrylene.

5. The luminescent solar collector of claim 1, wherein the non-fluorescent dye or pigment is present in an amount of from about 0.0001 weight percent to about 1 weight percent, based on the total weight of the second layer.

6. The luminescent solar collector of claim 1, wherein the second layer further comprises a diffuser.

7. The luminescent solar collector of claim 6, wherein the diffuser is an organic diffuser.

8. The luminescent solar collector of claim 7, wherein the organic diffuser has a D₅₀ particle size of from about 1 micrometer to about 100 micrometers.

9. The luminescent solar collector of claim 7, wherein the organic diffuser is selected from the group consisting of poly(acrylates); poly(alkyl methacrylates); poly (tetrafluoroethylene); silicones; hydrolyzed poly(alkyl trialkoxysilanes); and mixtures thereof, wherein the alkyl groups have from one to about twelve carbon atoms.

10. The luminescent solar collector of claim 7, wherein the organic diffuser is present in an amount of from about 0.0001 weight percent to about 0.2 weight percent, based on the total weight of the second layer.

11. The luminescent solar collector of claim 1, wherein the sheet provides an edge emission of at least 50 W/m².

12. The luminescent solar collector of claim 1, wherein the non-fluorescent dye or pigment has a wavelength of maximum absorbance greater than 400 nanometers.

13. A luminescent solar collector with a customizable viewing color, comprising a sheet and a photocell;
the sheet comprising a fluorescent layer and a translucent layer operatively connected to the fluorescent layer along an adjoining surface;
the photocell operatively connected to the fluorescent layer;
the fluorescent layer comprising a first polymer and a fluorescent dye or quantum dot dispersed therein, wherein the fluorescent dye or quantum dot absorbs light and radiates the absorbed light at a longer wavelength, and wherein the fluorescent layer is configured in a manner to transmit the radiated light to the photocell; and
the translucent layer comprising a second polymer having a diffuser and a non-fluorescent dye or pigment dispersed within, wherein the non-fluorescent dye or pigment contributes to the customizable viewing color of the luminescent solar collector.

14. The luminescent solar collector of claim 13, wherein the fluorescent dye or quantum dot is present in an amount of from about 0.0001 weight percent to about 1 weight percent, based on the total weight of the fluorescent layer.

15. The luminescent solar collector of claim 13, wherein the non-fluorescent dye is present in an amount of from about 0.0001 weight percent to about 1 weight percent, based on the total weight of the translucent layer.

16. The luminescent solar collector of claim 13, wherein the diffuser is present in an amount of from 0.001 to 0.2 weight percent, based on the total weight of the translucent layer.

17. The luminescent solar collector of claim 13, wherein the diffuser is an organic pigment.

18. The luminescent solar collector of claim 13, wherein the sheet provides an edge emission of at least 90 W/m².

19. A luminescent solar collector with a preselected external color, comprising a sheet and a photocell;
the sheet comprising a first layer and a second layer at least partially covering the first layer;
the first layer comprising a first polymer and a fluorescent dye or quantum dot;
the second layer comprising a second polymer and a non-fluorescent dye dispersed therein, wherein the non-fluorescent dye contributes to the preselected external color of the luminescent solar collector; and
wherein the sheet provides an edge emission of at least 50 W/m².

20. The luminescent solar collector of claim 19, wherein the sheet provides an edge emission of at least 70 W/m².

21. The luminescent solar collector of claim 19, wherein the viewing color of the non-fluorescent dye of the second layer differs from the viewing color of the fluorescent dye or quantum dot of the first layer.
